(19) United States
(12) Patent Application Publication
(10) Pub. No.: US 2026/0059884 A1
(43) Pub. Date: Feb. 26, 2026

(54) IMAGE SENSOR AND SEMICONDUCTOR DEVICE INCLUDING THE SAME

(71) Applicant: SAMSUNG ELECTRONICS CO., LTD., Suwon-si (KR)

(72) Inventors: Yongkun Jo, Suwon-si (KR); Sungmin Son, Suwon-si (KR); Juyoung You, Suwon-si (KR); Minho Jang, Suwon-si (KR)

(73) Assignee: SAMSUNG ELECTRONICS CO., LTD., Suwon-si (KR)

(21) Appl. No.: 19/217,707

(22) Filed: May 23, 2025

(30) Foreign Application Priority Data
Aug. 22, 2024 (KR) 10-2024-0112847

(51) Int. Cl. H10F 39/00; H01L 23/00; H01L 23/522

(52) U.S. Cl. CPC H10F 39/809; H01L 23/5225; H01L 24/05; H01L 24/08; H01L 24/80; H10F 39/018; H10F 39/811; H01L 2224/05016; H01L 2224/08145; H01L 2224/80895; H01L 2224/80896

(57) ABSTRACT

An image sensor is provided. The image sensor includes a first semiconductor structure with photodiodes provided in a first semiconductor substrate, a first interconnection structure below the first semiconductor substrate, first bonding structures below the first interconnection structure and connected to the first interconnection structure, first shielding structures between the first bonding structures, and a first bonding insulating film surrounding lower regions of the first bonding structures and lower regions of the first shielding structures; and a second semiconductor structure a second interconnection structure provided in a second semiconductor substrate, second bonding structures contacting the first bonding structures on the second interconnection structure and connected to the second interconnection structure, second shielding structures between the second bonding structures and contacting the first shielding structures, and a second bonding insulating film surrounding upper regions of the second bonding structures and upper regions of the second shielding structures.

### CROSS-REFERENCE TO RELATED APPLICATION

This application claims priority to Korean Patent Application No. 10-2024-0112847, filed on Aug. 22, 2024, in the Korean Intellectual Property Office, the disclosure of which is incorporated herein by reference in its entirety.

### BACKGROUND

The present disclosure relates to an image sensor and a semiconductor device including the same.

An image sensor may be a semiconductor-based sensor which generates an electric signal based on received light, and may include a pixel array having a plurality of unit pixels, and a circuit which drives the pixel array and generates an image. The plurality of unit pixels may each include a photodiode that generates a charge in response to light, and a pixel circuit that converts the charge generated by the photodiode into an electric signal, etc. The image sensor may be provided in smartphones, tablet personal computers, laptop computers, televisions, automobiles, cameras or other devices which captures pictures or videos.

### SUMMARY

One or more embodiments provide an image sensor having improved electrical reliability and a semiconductor device including the same.

According to an aspect of an embodiment, an image sensor includes: a first semiconductor structure including a first semiconductor substrate, a plurality of photodiodes provided in a first region of the first semiconductor substrate, a first interconnection structure below the first semiconductor substrate, first bonding structures below the first interconnection structure and connected to the first interconnection structure, first shielding structures between the first bonding structures, and a first bonding insulating film surrounding lower regions of the first bonding structures and lower regions of the first shielding structures; a second semiconductor structure including a second semiconductor substrate, a second interconnection structure provided in the second semiconductor substrate, second bonding structures contacting the first bonding structures on the second interconnection structure and connected to the second interconnection structure, second shielding structures between the second bonding structures and contacting the first shielding structures, and a second bonding insulating film surrounding upper regions of the second bonding structures and upper regions of the second shielding structures; and a third semiconductor structure including a third semiconductor substrate below the second semiconductor structure, and a third interconnection structure between the third semiconductor substrate and the second semiconductor structure, wherein the third interconnection structure is electrically connected to the second interconnection structure. Each of the first bonding structures includes a first portion connected to the first interconnection structure and having a first side surface, a second portion having a second side surface extending from the first side surface and having a width that increases with proximity to the second semiconductor structure, and a third portion having a third side surface extending from the second side surface and at least partially contacting the first bonding insulating film. A first width of the first portion is less than a second width of the third portion.

According to another aspect of an embodiment, an image sensor includes: a first semiconductor structure including a first semiconductor substrate having a first surface and a second surface opposite to the first surface, photodiodes provided in the first semiconductor substrate, first to third pixel isolation structures spaced apart from each other in the first semiconductor substrate and defining regions in which the photodiodes are provided, color filters on the first surface of the first semiconductor substrate, a first interconnection structure below the second surface, a first insulating liner on a lower surface of the first interconnection structure, first and second upper bonding structures penetrating the first insulating liner and connected to the first interconnection structure, and a first shielding structure between the first and second upper bonding structures; and a second semiconductor structure including a second semiconductor substrate having a third surface and a fourth surface opposite to the third surface, a second interconnection structure on the third surface of the second semiconductor substrate, a second insulating liner on the second interconnection structure, first and second intermediate bonding structures respectively contacting the first and second upper bonding structures penetrating the second insulating liner and connected to the second interconnection structure, and a second shielding structure between the first and second intermediate bonding structures and contacting the first shielding structure. The first upper bonding structure overlaps a first region of the first semiconductor substrate. A first photodiode among the photodiodes is provided in the first region of the first semiconductor substrate between the first pixel isolation structure and the second pixel isolation structure. The second upper bonding structure overlaps a second region of the first semiconductor substrate in which a second photodiode among the photodiodes is provided between the second pixel isolation structure and the third pixel isolation structure. Each of the first and second upper bonding structures includes a plug portion contacting the first interconnection structure and having a first width, an extension portion extending from the plug portion in a downward direction and having a width that increases along the downward direction, and a pad portion extending from the extension portion in the downward direction and having a second width, greater than the first width.

According to another aspect of an embodiment, a semiconductor device includes: a first semiconductor structure including a first semiconductor substrate, a first interconnection structure below the first semiconductor substrate, first bonding structures exposed from a lower surface of the first interconnection structure, and a first bonding insulating film surrounding lower regions of the first bonding structures; a second semiconductor structure including a second semiconductor substrate, a second interconnection structure on the second semiconductor substrate, second bonding structures exposed from an upper surface of the second interconnection structure and bonded to each of the first bonding structures, a second bonding insulating film surrounding upper regions of the second bonding structures, a first backside insulating layer on a lower surface of the second semiconductor substrate, a third bonding insulating film on the first backside insulating layer, and a conductive through-via, wherein the conductive through-via overlaps the third bonding insulating film and the first backside insulating layer, and is electrically connected to the second interconnection structure; and a third semiconductor structure including a third semiconductor substrate, a third interconnection structure on an upper surface of the third semiconductor substrate, a fourth bonding insulating film on the third interconnection structure and contacting the third bonding insulating film, and a bonding pad electrically connected to the third interconnection structure and bonded to the conductive through-via. Each of the first bonding structures includes a first plug portion contacting the first interconnection structure and having a first side surface, a first connection portion having a second side surface extending from the first side surface and having a width that increases with proximity to the second semiconductor structure, and a first pad portion extending from the second side surface and having a third side surface at least partially contacting the first bonding insulating film. Each of the second bonding structures includes a second plug portion contacting the second interconnection structure and having a fourth side surface, a second connection portion having a fifth side surface extending from the fourth side surface and having a width that increases with proximity to the first semiconductor structure, and a second pad portion extending from the fifth side surface and having a sixth side surface at least partially contacting the second bonding insulating film.

### BRIEF DESCRIPTION OF DRAWINGS

The above and other aspects, features, and advantages will be more apparent from the following description of embodiments, taken in conjunction with the accompanying drawings, in which:

FIG. 1 is a block diagram illustrating an image sensor according to embodiments.

FIG. 2 is a circuit diagram of pixels constituting a pixel array of the image sensor of FIG. 1 according to embodiments.

FIG. 3 is an exploded perspective view illustrating an image sensor according to an embodiment.

FIG. 4 is a cross-sectional view illustrating the image sensor of FIG. 2, taken along lines I-I′ and II-II′ according to an embodiment.

FIGS. 5A, 5B, 5C, 5D, 5E, 5F and 5G are enlarged views illustrating portion A of the image sensor of FIG. 4 according to embodiments.

FIGS. 6A and 6B are plan views schematically illustrating first bonding structures (or second bonding structures) and first shielding structures (or second shielding structures) of the image sensor of FIG. 4 according to embodiments.

FIGS. 7A, 7B, 7C, 7D, 7E, 7F, 7G, 7H, 7I, 7J, 7K and 7L are cross-sectional views of forming first bonding structures and first shielding structures according to a manufacturing method according to an embodiment.

### DETAILED DESCRIPTION

Hereinafter, embodiments are described with reference to the accompanying drawings. The same reference numerals may be used for the same components in the drawings, and duplicate descriptions of the same components will be omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

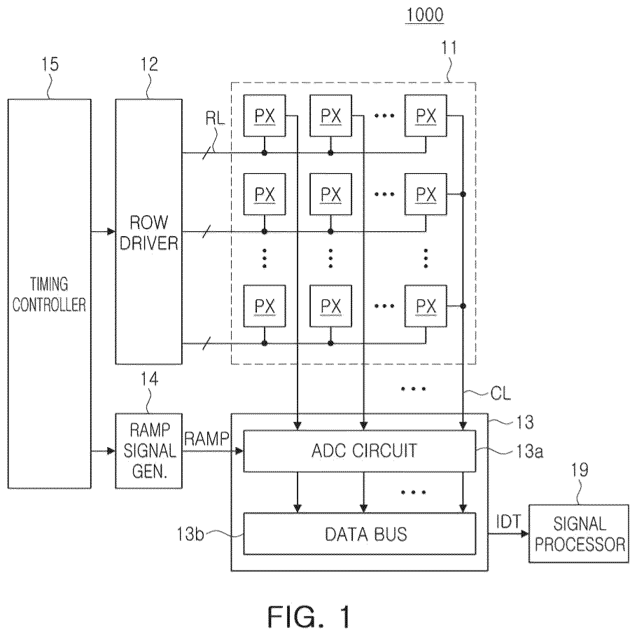

FIG. 1 is a block diagram illustrating an image sensor according to embodiments.

Referring to FIG. 1, an image sensor 1000 according to may include a pixel array 11, a row driver (i.e., row driver circuit) 12, a readout circuit 13, a ramp signal generator (i.e., ramp signal generation circuit) 14, a timing controller (i.e., timing control circuit) 15, and a signal processing unit (i.e., signal processing circuit) 19. The readout circuit 13 may include an analog-to-digital conversion circuit 13a (hereinafter, referred to as an ADC circuit) and a data bus 13b.

The pixel array 11 may include a plurality of row lines RL and a plurality of column lines CL. The pixel array 11 may include a plurality of pixels PX connected to the plurality of row lines RL and the plurality of column lines CL, and disposed in rows and columns. The plurality of pixels PX may be an active pixel sensor (APS).

Each of the plurality of pixels PX may include at least one photoelectric conversion element, and the pixel PX may detect light using the photoelectric conversion element, and may output an image signal, which may be an electrical signal converted from the detected light. For example, the photoelectric conversion element may include a photodiode, a phototransistor, a photogate, a pinned photodiode, or the like.

Each of the plurality of pixels PX may detect light of a specific spectrum region. For example, some of the plurality of pixels PX may convert light of a red spectrum region into an electrical signal, light of a green spectrum region into an electrical signal, or light of a blue spectrum region into an electrical signal. However, embodiments are not limited thereto, and at least some of the plurality of pixels PX may convert light of a white spectrum region into an electrical signal. In another embodiment, at least some of the plurality of pixels PX may convert light of another color spectrum region into an electrical signal. For example, at least some of the plurality of pixels PX may convert light of one of the spectral regions of yellow, cyan, or magenta into an electrical signal.

A color filter may be disposed above each of the plurality of pixels PX to transmit light of a specific spectral region. Depending on the color filter, a color that a pixel PX corresponding thereto detects may be determined. However, embodiments are not limited thereto. In some embodiments, a specific photoelectric conversion element may convert light of a specific wavelength band into an electrical signal, depending on a level of the electrical signal applied to the photoelectric conversion element.

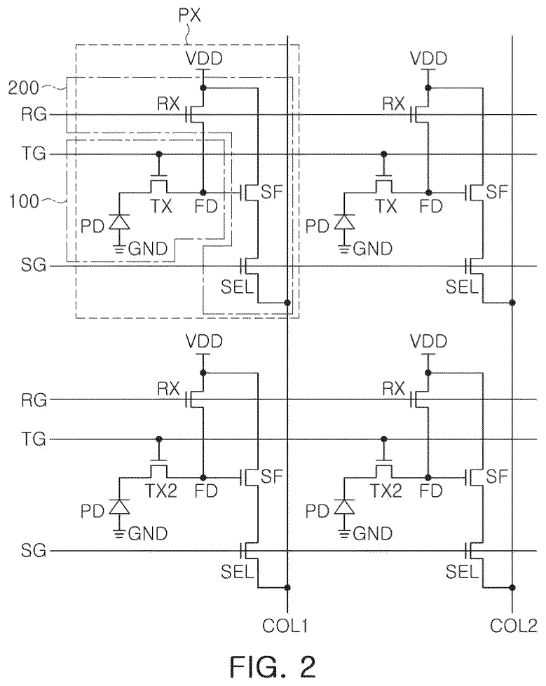

Each of the plurality of pixels PX may have a dual conversion gain. The dual conversion gain may include a low conversion gain and a high conversion gain. The dual conversion gain refers to a rate at which charges accumulated in a floating diffusion node (e.g., floating diffusion node FD of FIG. 2) are converted into a voltage. Charges generated in the photoelectric conversion element may be transferred to and accumulated in the floating diffusion node, and may be transferred to and accumulated in the floating diffusion node, according to a conversion gain, and the charges accumulated in the floating diffusion node may be converted into a voltage, according to the conversion gain. In this case, the conversion gain may be changed according to capacitance of the floating diffusion node, and when the capacitance of the floating diffusion node increases, the conversion gain may decrease, and when the capacitance of the floating diffusion node decreases, the conversion gain may increase.

Each of the plurality of row lines RL may extend in a row direction, and may be connected to pixels PX disposed in the same row.

Each of the plurality of column lines CL extends in a column direction, and may be connected to pixels PX disposed in the same column. Each of the plurality of column lines CL may transmit a reset signal and a sensing signal of the pixels PX in a row unit of the pixel array 11 to the readout circuit 13.

The timing controller 15 may control timing of the row driver 12, timing of the readout circuit 13, and timing of the ramp signal generator 14. Timing signals indicating operation timing may be provided from the timing controller 15 to the row driver 12, the readout circuit 13, and the ramp signal generator 14, respectively.

The row driver 12 may drive the pixel array 11 in a row unit. The row driver 12 may decode a row control signal (e.g., address signal) received from the timing controller 15. The row driver 12 may select at least one row line RL, among the plurality of row lines RL, constituting the pixel array 11 according to the decoded row control signal.

The row driver 12 may generate a select signal for selecting one of the plurality of rows. The select signal may be transmitted to the pixel array 11 through the row lines RL. The pixel array 11 may output a pixel signal (e.g., pixel voltage) from a row selected by the select signal provided from the row driver 12. The pixel signal may include a reset signal and an image signal. The row driver 12 may transmit control signals to the pixel array 11. The plurality of pixels PX may output a pixel signal by operating according to the control signals.

The ramp signal generator 14 may generate a ramp signal (e.g., ramp voltage) of which level rises or falls at a predetermined slope according to control of the timing controller 15. The ramp signal RAMP may be provided to the ADC circuit 13a.

The ADC circuit 13a may convert the pixel signal input from the pixel array 11 into a pixel value, which may be a digital signal. Each pixel signal received through the plurality of column lines CL may be converted into a pixel value, which may be a digital signal, by the ADC circuit 13a. In an example, the ADC circuit 13a may include a plurality of ADCs corresponding to the plurality of column lines CL. Each of the plurality of ADCs may compare a reset signal and a sensing signal, received through a plurality of column lines CL, corresponding thereto, with a ramp signal RAMP, respectively, and may generate a pixel value based on a comparison result. For example, the ADC may remove the reset signal from the sensing signal, and may generate a pixel value representing an amount of light detected in a pixel PX.

A plurality of pixel values generated from the ADC circuit 13a may be output as image data IDT through the data bus 13b. For example, the image data IDT may be provided to image signal processor 19. For example, the image signal processor 19 may be provided inside or outside the image sensor 1000.

The data bus 13b may temporarily store the pixel values output from the ADC circuit 13a, and may then output the same. The data bus 13b may include a plurality of column memories, and a column decoder. A plurality of pixel values stored in the plurality of column memories may be output as the image data IDT under control of the column decoder.

The ADC circuit 13a may include a plurality of correlated double sampling (CDS) circuits and a plurality of counter circuits. The ADC circuit 13a may convert the pixel signal (e.g., pixel voltage) input from the pixel array 11 into a pixel value, which may be a digital signal. Each pixel signal received through the plurality of column lines CL may be converted into a pixel value, which may be a digital signal, by the CDS circuit and the counter circuit.

The CDS circuit may compare a pixel signal received through the column line CL with a ramp signal RAMP, and may output a comparison result. When a level of the ramp signal RAMP and a level of the pixel signal are the same, the CDS circuit may output a comparison signal transitioning from a first level (e.g., logic high) to a second level (e.g., logic low). A point in time when a level of the comparison signal transitions may be determined according to the level of the pixel signal. The CDS circuit may sample and hold a pixel signal provided from a pixel PX according to a correlated double sampling (CDS) method, and may double sample a level according to a specific noise level (e.g., reset signal) and an image signal (e.g., sensing signal), and may generate a comparison signal, based on a level corresponding to a difference therebetween. In another embodiment, the CDS circuit may include one or more comparators. The comparator may be implemented as, for example, an operational transconductance amplifier (OTA) (or a differential amplifier). The ADC circuit 13a may include a plurality of delta reset sampling (DRS) circuits. The DRS circuit may sample a pixel signal provided by first reading out a pixel signal and then reading out a reset signal according to a delta reset sampling (DRS) method.

The signal processing unit 19 may perform noise reduction processing, gain adjustment, waveform standardization processing, interpolation processing, white balance processing, gamma processing, edge emphasis processing, binning, or the like on image data.

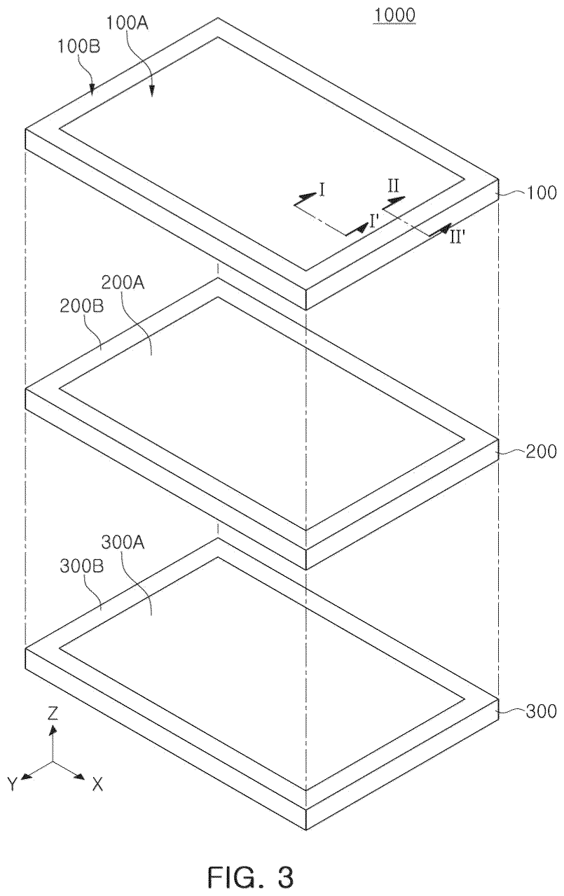

FIG. 2 is a circuit diagram of pixels constituting a pixel array of the image sensor of FIG. 1. FIG. 3 is an exploded perspective view illustrating an image sensor according to an embodiment.

Referring to FIGS. 2 and 3, an image sensor 1000 may include a plurality of semiconductor structures sequentially stacked in a vertical direction (Z-direction). The image sensor 1000 may include a first semiconductor structure 100, a second semiconductor structure 200, and a third semiconductor structure 300, sequentially stacked in the vertical direction (Z-direction). Each of the first semiconductor structure 100, the second semiconductor structure 200, and the third semiconductor structure 300 may include a main region (100A, 200A, and 300A) and a peripheral region (100B, 200B, and 300B) surrounding the main region (100A, 200A, and 300A).

The main regions 100A and 200A of the first and second semiconductor structures 100 and 200 may constitute a pixel array (e.g., pixel array 11 of FIG. 1). Elements of pixels PX constituting a pixel array 11 may be divided and disposed in the first semiconductor structure 100 and the second semiconductor structure 200. For example, a plurality of photoelectric conversion elements PD, a plurality of floating diffusion nodes FD, a plurality of transfer transistors TX having a plurality of transfer gates TG, and a ground region GND may be disposed in the first semiconductor structure 100. A plurality of reset transistors RX, a plurality of source-follower transistors SF, and a plurality of select transistors SEL may be disposed in the second semiconductor structure 200.

The main region 300A of the third semiconductor structure 300 may include logic circuits, and the logic circuits may include, but are not limited to, the row driver 12, the readout circuit 13, the ramp signal generator 14, the timing controller 15, and the signal processing unit 19 of FIG. 1, and some of the logic circuits may be disposed in the main region 200A of the second semiconductor structure 200. Peripheral circuits (e.g., input/output circuits) connected to the circuits of the main region (100A, 200A, and 300A) may be disposed in the peripheral regions (100B, 200B, and 300B) of the first, second, and third semiconductor structures 100, 200, and 300, respectively.

Each of the plurality of pixels PX may include a pixel circuit including the photoelectric conversion element PD, and the pixel circuit may include the transfer transistor TX, the reset transistor RX, the select transistor SEL, and the source-follower transistor SF. In addition, the pixel circuit may further include a floating diffusion node FD in which charges generated from the photoelectric conversion element PD are accumulated. The photoelectric conversion element PD will be described as a photodiode, which may be an example of the photoelectric conversion element PD.

The photodiode PD may generate and accumulate charges in response to externally incident light. The photodiode PD may be replaced with a phototransistor, a photogate, a pinned photodiode, or the like according to embodiments.

The transfer transistor TX may be turned on or off by a transfer gate signal input to the transfer gate TG. The transfer transistor TX may transfer charges generated from the photodiode PD to the floating diffusion node FD. The floating diffusion node FD may store the charges generated from the photodiode PD. Depending on amounts of the charges accumulated in the floating diffusion node FD, a voltage output by the source-follower transistor SF may be changed.

The reset transistor RX may reset a voltage of the floating diffusion node FD by removing the charges accumulated in the floating diffusion node FD. A drain electrode of the reset transistor RX may be connected to the floating diffusion node FD, and a source electrode of the reset transistor RX may be connected to a power supply voltage VDD. When the reset transistor RX is turned on, the power supply voltage VDD connected to the source electrode of the reset transistor RX may be applied to the floating diffusion node FD, and the charges accumulated in the floating diffusion node FD may be removed.

The source-follower transistor SF may operate as a source follower buffer amplifier. The source-follower transistor SF may amplify voltage change of the floating diffusion node FD, and may output the same to one of column lines COL1 and COL2.

The select transistor SEL may select pixels PX to be read in a row unit. The select transistor SEL may output to one of the pixels PX to be read in a row unit. When the select transistor SEL is turned on, a voltage of the source-follower transistor SF may be output to one of the column lines COL1 and COL2. For example, when the select transistor SEL is turned on, a reset voltage or a pixel voltage may be output through the column lines COL1 and COL2.

The plurality of pixels PX may further include a ground region GND that may receive a ground voltage.

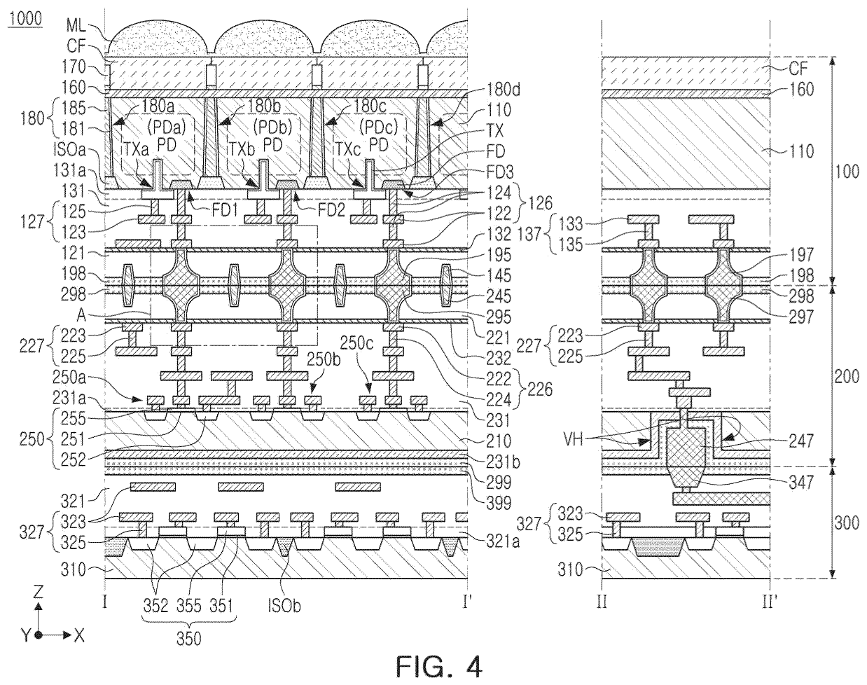

FIG. 4 is a cross-sectional view illustrating an embodiment of the image sensor of FIG. 2, taken along lines I-I′ and II-II′. The left portion of FIG. 4 is a cross-sectional view taken along line I-I′ of a main region of the image sensor of FIG. 2, and the right portion of FIG. 4 is a cross-sectional view taken along line II-II′ of a peripheral region of the image sensor of FIG. 2.

Referring to FIG. 4, an image sensor 1000 may include a third semiconductor structure 300, a second semiconductor structure 200 on the third semiconductor structure 300, and a first semiconductor structure 100 on the second semiconductor structure 200. In this regard, the third semiconductor structure 300, the second semiconductor structure 200 and the first semiconductor structure 100 may be sequentially stacked in the vertical direction (Z-direction). In an example, the image sensor 1000 may be composed of three semiconductor structures in which the first semiconductor structure 100, the second semiconductor structure 200, and the third semiconductor structure 300 are bonded to each other, but embodiments are not limited thereto. For example, according to another embodiment, the image sensor may be composed of only two semiconductor structures in which the first and second semiconductor structures 100 and 200 are bonded to each other.

The first to third semiconductor structures 100, 200, and 300 may respectively include first to third semiconductor substrates 110, 210, and 310.

Each of the first to third semiconductor substrates 110, 210, and 310 may be a silicon substrate, or a semiconductor substrate such as silicon germanium.

An upper surface of the first semiconductor substrate 110 may be referred to as a first surface or a back surface, and a lower surface of the first semiconductor substrate 110 may be referred to as a second surface or a front surface.

The first semiconductor structure 100 may include photodiodes PD and pixel isolation structures 180 defining regions in which the photodiodes PD are disposed. The photodiodes PD and the pixel isolation structures 180 may be disposed in a main region (e.g., main region 100A of FIG. 2) of the first semiconductor structure 100. The upper surface (or back surface) of the first semiconductor substrate 110 may be a light-receiving surface on which light is incident.

The pixel isolation structures 180 may be disposed between each of the photodiodes PD and may define regions in which the photodiodes PD are disposed. For example, the pixel isolation structures 180 may physically and electrically isolate the photodiodes PD from each other. The pixel isolation structure 180 may have a front deep trench isolation (FDTI) structure penetrating from the front surface (or second surface) of the first semiconductor substrate 110 to the back surface (or first surface) of the first semiconductor substrate 110. In another embodiment, the pixel isolation structure 180 may have a back deep trench isolation (BDTI) structure penetrating from the back surface (or first surface) of the first semiconductor substrate 110 to the back surface (or second surface) of the first semiconductor substrate 110. In an example, the pixel isolation structures 180 may also define regions in which transfer transistors TX and floating diffusion nodes FD are disposed.

A deep trench for the pixel isolation structure 180 may be formed in the first semiconductor substrate 110. The pixel isolation structure 180 may include an insulating film 181 conformally formed on an inner surface of the trench, and a conductive layer 185 filling the trench on the insulating film 181. For example, the insulating film 181 may include silicon oxide, silicon nitride, silicon oxynitride, hafnium oxide, aluminum oxide, or tantalum oxide. The conductive layer 185 may include at least one of doped polysilicon, a metal, a metal silicide, a metal nitride, or a metal-containing film.

The lower surface (or front surface) of the first semiconductor substrate 110 may be provided as an active surface. The transfer transistor TX may be formed on the lower surface of the first semiconductor substrate 110. An element isolation pattern ISOa may define an active region in which the transfer transistor TX is to be formed in the first semiconductor substrate 110. The element isolation pattern ISOa may be formed, for example, by filling an insulating material in a shallow trench formed by patterning the first semiconductor substrate 110. The transfer transistors TX may be disposed between the pixel isolation structures 180. For example, the transfer transistors TX may be disposed in a region adjacent to the photodiodes PD disposed between the pixel isolation structures 180.

The transfer transistor TX may include a transfer gate including an upper portion extending into the first semiconductor substrate 110 and a lower portion connected to the upper portion and protruding onto the lower surface of the semiconductor substrate 110. The floating diffusion node FD may be disposed in a space of the first semiconductor substrate 110 adjacent to one side of a transfer transistor TX and the lower surface of the first semiconductor substrate 110.

A plurality of photodiodes PD, a plurality of transfer transistors TX, and a plurality of floating diffusion nodes FD may be disposed in a plurality of pixel regions defined by the pixel isolation structures 180.

The pixel isolation structures 180 may include first to fourth pixel isolation structures 180a to 180d spaced apart in a first direction (X-direction). In an example, a first photodiode PDa may be disposed between the first pixel isolation structure 180a and the second pixel isolation structure 180b, a second photodiode PDb may be disposed between the second pixel isolation structure 180b and the third pixel isolation structure 180c, and a third photodiode PDc may be disposed between the third pixel isolation structure 180c and the fourth pixel isolation structure 180d. A first transfer transistor TXa and a first floating diffusion node FD1 may be disposed in a region adjacent to the lower surface of the first semiconductor substrate 110 on which the first photodiode PDa is disposed. A second transfer transistor TXb and a second floating diffusion node FD2 may be disposed in a region adjacent to the lower surface of the first semiconductor substrate 110 on which the second photodiode PDb is disposed. A third transfer transistor TXc and a third floating diffusion node FD3 may be disposed in a region adjacent to the lower surface of the first semiconductor substrate 110 on which the third photodiode PDc is disposed.

The image sensor 1000 may include an insulating material layer 160 disposed on the upper surface of the first semiconductor substrate 110. The image sensor 1000 may include an anti-reflection film, a color filter CF and a micro lens ML disposed on the insulating material layer 160. The color filter CF may be disposed in each of a plurality of pixel regions defined by an insulating grid structure 170. The micro lens ML may be disposed on the photodiode PD, and may be configured to collect external light incident thereon, and to cause the same to be incident on the photodiode PD. The color filter CF may selectively transmit an optical signal of a specific wavelength band.

A first interlayer insulating film 131a surrounding the transfer transistor TX may be disposed on the lower surface of the first semiconductor substrate 110.

A first interconnection structure (126 and 127) disposed on the lower surface of the first semiconductor substrate 110 may include a first upper interconnection layer 126 and a second upper interconnection layer 127 distinct from the first upper interconnection layer 126. The first upper interconnection layer 126 and the second upper interconnection layer 127 may be disposed in a first upper insulating layer 131. The first upper insulating layer 131 may be disposed below the first interlayer insulating film 131a, and may be in contact with a lower surface of the first interlayer insulating film 131a. In an example, the first upper insulating layer 131 may include an insulating material, for example, silicon oxide. The first upper interconnection layer 126 may be connected to the floating diffusion node FD. For example, the first upper interconnection layer 126 may penetrate the first upper insulating layer 131 and the first interlayer insulating film 131a to the floating diffusion node FD. The second upper interconnection layer 127 may be connected to the transfer transistor TX. For example, the second upper interconnection layer 127 may penetrate the first upper insulating layer 131 to the transfer transistor TX. In an example, the first upper interconnection layer 126 may include first upper interconnection lines 122 and first upper interconnection vias 124 connected to the first upper interconnection lines 122. The second upper interconnection layer 127 may include second upper interconnection lines 123 and second upper interconnection vias 125 connected to the second upper interconnection lines 123. For example, each of the first upper interconnection layer 126 and the second upper interconnection layer 127 may include copper or a copper alloy.

A first insulating liner 132 may be disposed on a lower surface of the first interconnection structure (126 and 127). The first insulating liner 132 may be in contact with a lower surface of the first upper insulating layer 131. The first insulating liner 132 may include an insulating material. In an example, the first insulating liner 132 may include an insulating material, different from the first upper insulating layer 131 and a second upper insulating layer 121, and may be formed of an insulating material such as, for example, silicon nitride, SiBN, SiCN, an insulating metal oxide, or the like.

First bonding structures 195 and first shielding structures 145 disposed between the first bonding structures 195 may be disposed below the first interconnection structure (126 and 127).

The first bonding structures 195 may be connected to the first upper interconnection layer 126 through the first insulating liner 132. The first bonding structures 195 may be electrically connected to the floating diffusion nodes FD through the first upper interconnection layer 126. The first bonding structures 195 may be respectively connected to first to third floating diffusion nodes FD1 to FD3. In an example, a first bonding structure connected to the first floating diffusion node FD1, among the first bonding structures 195, may be referred to as a first upper bonding structure, a first bonding structure connected to the second floating diffusion node FD2, among the first bonding structures 195, may be referred to as a second upper bonding structure, and a first bonding structure connected to the third floating diffusion node FD3, among the first bonding structures 195, may be referred to as a third upper bonding structure. The first upper bonding structure may overlap the first photodiode PDa in the vertical direction (Z-direction), the second upper bonding structure may overlap the second photodiode PDb in the vertical direction (Z-direction), and the third upper bonding structure may overlap the third photodiode PDc in the vertical direction (Z-direction).

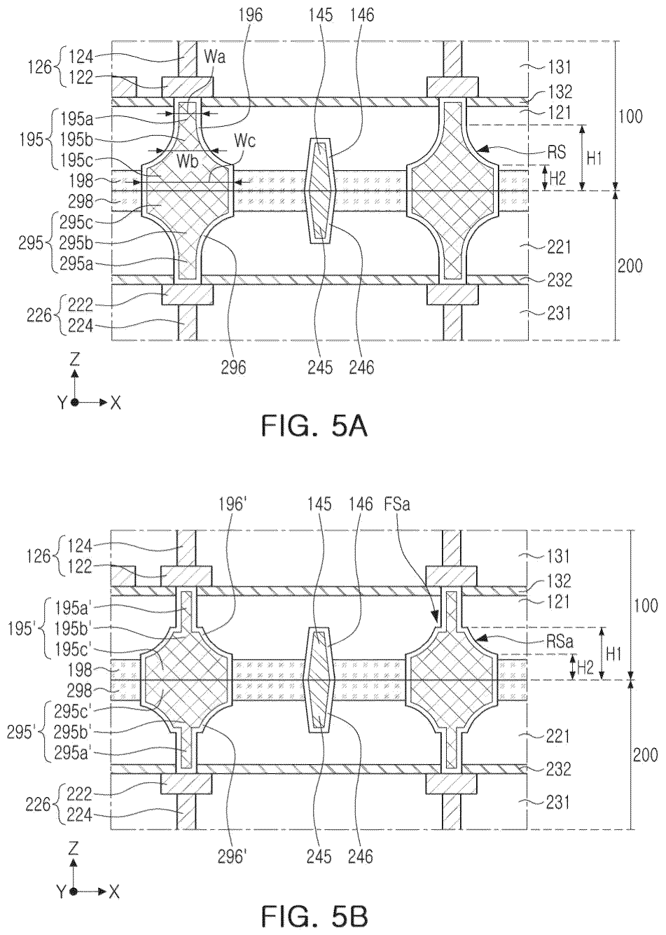

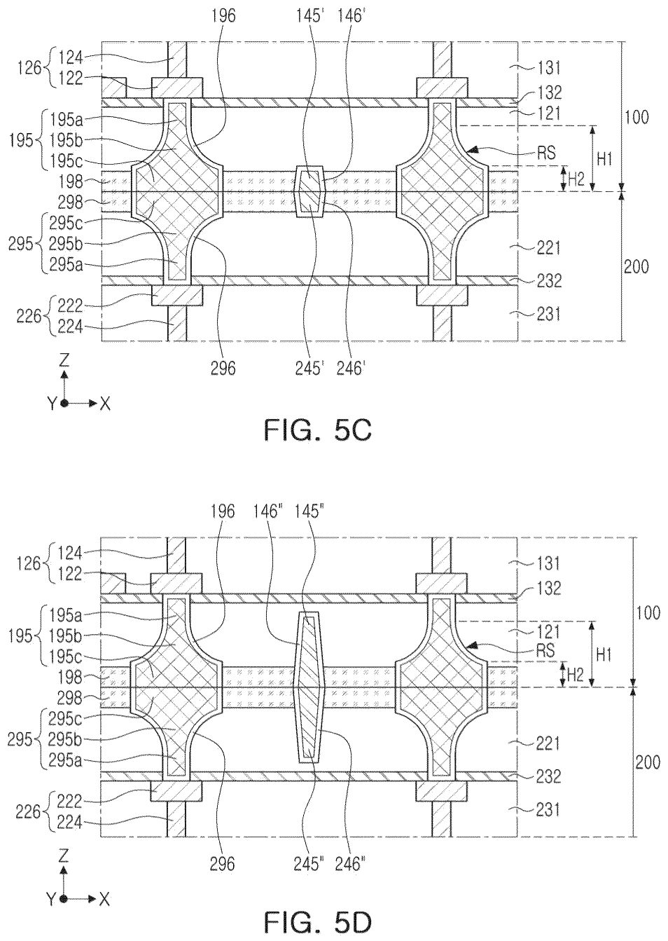

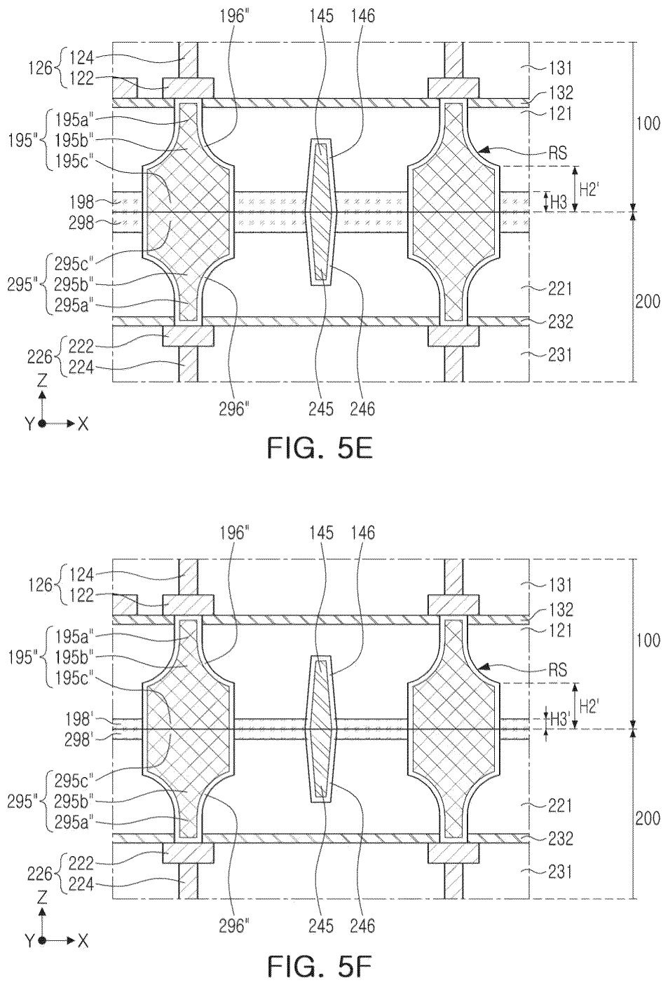

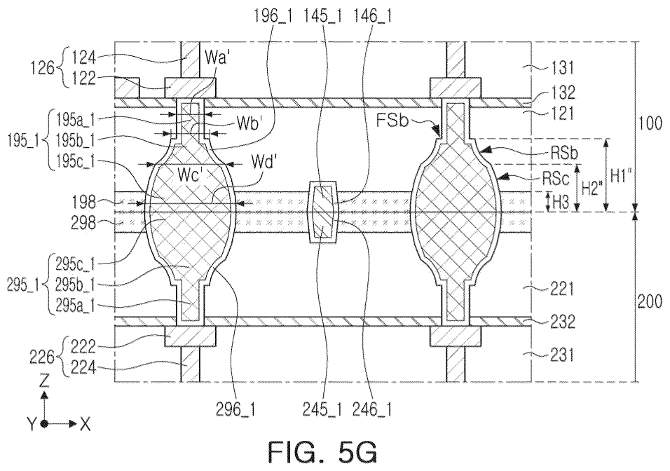

The first bonding structures 195 may include a plug portion (e.g., first portion 195a of FIG. 5A) penetrating the first insulating liner 132 and connected to the first upper interconnection layer 126, a pad portion (e.g., second portion 195b of FIG. 5A) having a lower surface that is exposed by a first bonding insulating film 198, and a connection portion (e.g., third portion 195c of FIG. 5A) extending from the plug portion between the plug portion and the pad portion and having a width increasing in a downward direction. A shape of the first bonding structures 195 will be described below with reference to FIGS. 5A to 5G. In an example, the first bonding structures 195 may include a metal material such as copper (Cu). In an example, the first bonding structure 195 of the first semiconductor structure 100 may be bonded to a second bonding structure 295 of the second semiconductor structure 200. The first bonding structure 195 may be vertically symmetrical to the second bonding structure 295.

The first shielding structures 145 may be disposed between the first bonding structures 195 and spaced apart from the first bonding structures 195 in the first direction (X-direction). The first shielding structures 145 may cover at least a portion of side surfaces of the first bonding structures 195 that face each other. The first shielding structures 145 may prevent a coupling phenomenon occurring between the first bonding structures 195. For example, the first shielding structure 145 disposed between the first upper bonding structure and the second upper bonding structure may prevent capacitance of the first floating diffusion node FD1 connected to the first upper bonding structure and capacitance of the second floating diffusion node FD2 connected to the second upper bonding structure, from increasing. Therefore, capacitance of the first and second floating diffusion nodes FD1 and FD2 may be prevented from increasing, thereby preventing a conversion gain from decreasing.

A lower surface of the first shielding structures 145 may be coplanar with a lower surface of the first bonding structures 195. A height of the first shielding structure 145 in the vertical direction (Z-direction) may be less than a height of the first bonding structure 195 in the vertical direction (Z-direction). The height of the first shielding structure 145 in the vertical direction (Z-direction) may be a distance from the lower surface of the first shielding structure 145 to an upper surface of the first shielding structure 145. The height of the first bonding structure 195 in the vertical direction (Z-direction) may be a distance from the lower surface of the first bonding structure 195 to an upper surface of the first bonding structure 195. The upper surface of the first shielding structure 145 may be disposed on a level lower than the first insulating liner 132. In an example, the upper surface of the first shielding structure 145 may be disposed on a lower level than the upper surface of the first bonding structure 195. In an example, each of the first shielding structures 145 may have a width decreasing in an upward direction. The first shielding structures 145 may include the same metal material as the first bonding structures 195. For example, the first shielding structures 145 may include copper (Cu). In an example, the first shielding structures 145 of the first semiconductor structure 100 may be in contact with second shielding structures 245 of the second semiconductor structure 200.

The first bonding insulating film 198 may surround lower regions of the first bonding structures 195 and lower regions of the first shielding structures 145. The first bonding insulating film 198 may expose lower surfaces of the first bonding structures 195 and lower surfaces of the first shielding structures 145. The lower surfaces of the first bonding insulating film 198, the lower surfaces of the first bonding structures 195, and the lower surfaces of the first shielding structures 145 may form a coplanar surface. In an example, the first bonding insulating film 198 of the first semiconductor structure 100 may be bonded to a second bonding insulating film 298 of the second semiconductor structure 200.

The second upper insulating layer 121 may be disposed between the first insulating liner 132 and the first bonding insulating film 198. The second upper insulating layer 121 may surround side surfaces of the first bonding structures 195 and side surfaces of the first shielding structures 145. The second upper insulating layer 121 may include an insulating material, for example, silicon oxide. In an example, the second upper insulating layer 121 may include the same insulating material as the first upper insulating layer 131.

The first semiconductor structure 100 may further include first peripheral bonding structures 197 disposed in a peripheral region (e.g., peripheral region 100B of FIG. 2) and first peripheral interconnections 137 connected to the first peripheral bonding structures 197. The first peripheral bonding structures 197 may penetrate the first insulating liner 132 to the peripheral region, to be connected to the first peripheral interconnections 137. The first peripheral interconnections 137 may include first peripheral interconnection lines 133 and first peripheral interconnection vias 135 connected to the first peripheral interconnection lines 133. The first peripheral bonding structures 197 may not be connected to the first peripheral interconnections 137, and may be disposed only for bonding. For example, the first peripheral bonding structures 197 may be electrically separated from the first peripheral interconnections 137. The first peripheral bonding structure 197 may have the same shape as the first bonding structure 195. The first bonding insulating film 198 may extend to the peripheral region and may surround the lower region of the first peripheral bonding structures 197, and may expose a lower surface of the first peripheral bonding structures 197. In an example, the lower surface of the first peripheral bonding structure 197 may be coplanar with the lower surface of the first bonding structure 195 and a lower surface of the first bonding insulating film 198. In an embodiment, the first peripheral bonding structure 197 may be in contact with a second peripheral bonding structure 297 of the second semiconductor structure 200. Side surfaces of the first peripheral bonding structures 197 may oppose each other. Shielding structures, such as the first shielding structures 145, may not be disposed between the first peripheral bonding structures 197.

The second semiconductor structure 200 may be disposed below the first semiconductor structure 100. The second semiconductor structure 200 may include a second semiconductor substrate 210, a second interconnection structure (226 and 227) on the second semiconductor substrate 210, a second insulating liner 232 on the second interconnection structure (226 and 227), second bonding structures 295 on the second interconnection structure (226 and 227), second shielding structures 245 between the second bonding structures 295, and a second bonding insulating film 298 exposing upper surfaces of the second bonding structures 295 and upper surfaces of the second shielding structures 245.

An upper surface of the second semiconductor substrate 210 may be referred to as a third surface or a front surface, and a lower surface of the second semiconductor substrate 210 may be referred to as a fourth surface or a back surface.

Pixel circuit elements 250 may be disposed on the second semiconductor substrate 210. The pixel circuit elements 250 may correspond to the source-follower transistor SF of FIG. 2.

Each of the pixel circuit elements 250 may include a gate electrode 255, a gate insulating film 251 between the gate electrode 255 and the second semiconductor substrate 210, and source/drain regions 252 doped with impurities at both sides of the gate electrode 255. A second interlayer insulating film 231a may be disposed on the upper surface (or third surface) of the second semiconductor substrate 210 and may surround the pixel circuit elements 250.

The second interconnection structure (226 and 227) disposed on the upper surface of the second semiconductor substrate 210 may include a first intermediate interconnection layer 226 and a second intermediate interconnection layer 227 distinct from the first intermediate interconnection layer 226. The first interconnection structure (226 and 227) may be disposed in a first intermediate insulating layer 231. The first intermediate insulating layer 231 may be disposed on the second interlayer insulating layer 231a, and may be in contact with an upper surface of the second interlayer insulating layer 231a. The first intermediate insulating layer 231 may include an insulating material, for example, silicon oxide. The first intermediate interconnection layer 226 may be connected to the pixel circuit elements 250, and the first intermediate interconnection layer 226 may include first intermediate interconnection lines 222 connected to gate electrodes 255 of the pixel circuit elements 250, and first intermediate interconnection vias 224 connected to the first intermediate interconnection lines 222. In an example, the second intermediate interconnection layer 227 may be an interconnection layer connected to the reset transistor RX, the select transistor SEL or other elements of FIG. 2, in addition to the source-follower transistor SF of FIG. 2. The second intermediate interconnection layer 227 may include second intermediate interconnection lines 223 and second intermediate interconnection vias 225 connecting the second intermediate interconnection lines 223.

The second insulating liner 232 may be disposed on an upper surface of the second interconnection structure (226 and 227). The second insulating liner 232 may be in contact with an upper surface of the first intermediate insulating layer 231. The second insulating liner 232 may include an insulating material. In an example, the second insulating liner 232 may include an insulating material different from the first intermediate insulating layer 231 and a second intermediate insulating layer 221, and may be formed of an insulating material such as, for example, silicon nitride, SiBN, SiCN, an insulating metal oxide, or the like.

A second bonding structure 295 may be disposed on the second interconnection structure (226 and 227) contacting the first bonding structure 195 and between second bonding structures 295, and second shielding structures 245 may be disposed to contact the first shielding structures 145.

The second bonding structures 295 may be vertically symmetrical with respect to the first bonding structures 195, based on an X-axis. The second shielding structures 245 may be vertically symmetrical with respect to the first shielding structures 145, based on the X-axis.

The second bonding structures 295 may be connected to the first intermediate interconnection layers 226. The second bonding structures 295 may penetrate the second insulating liner 232 to the first intermediate interconnection layers 226. The second bonding structures 295 may respectively be connected to the pixel circuit elements 250 through the first intermediate interconnection layers 226. The second bonding structures 295 may be respectively connected to first to third pixel circuit elements 250a to 250c.

Among the second bonding structures 295, a second bonding structure connected to a gate electrode 255 of the first pixel circuit element 250a may be referred to as a first intermediate bonding structure, and the first intermediate bonding structure may be in contact with a first upper bonding structure of the first bonding structures 195. Among the second bonding structures 295, a second bonding structure connected to a gate electrode 255 of the second pixel circuit element 250b may be referred to as a second intermediate bonding structure, and the second intermediate bonding structure may be in contact with a second upper bonding structure of the first bonding structures 195. Among the second bonding structures 295, a second bonding structure connected to a gate electrode 255 of the third pixel circuit element 250c may be referred to as a third intermediate bonding structure, and the third intermediate bonding structure may be in contact with a third upper bonding structure of the first bonding structures 195.

Each of the second bonding structures 295 may include a plug portion connected to the first intermediate interconnection layer 226, a pad portion having an upper surface that is exposed by the second bonding insulating film 298, and a connection portion extending from the plug portion between the plug portion and the pad portion and having a width increasing in an upward direction.

A floating diffusion node FD of the first semiconductor structure 100 and a pixel circuit element 250 of the second semiconductor structure 200 may be connected through the first upper interconnection layer 126 connected to the floating diffusion node FD, the first bonding structure 195, the second bonding structure 295, and the first intermediate interconnection layer 226 connected to the pixel circuit element 250.

The second shielding structures 245 may be disposed between the second bonding structures 295, and may be spaced apart from the second bonding structures 295 in the first direction (X-direction). The second shielding structures 245 may cover at least a portion of side surfaces of the second bonding structures 295 that face each other. In an example, the second shielding structures 245 may prevent a coupling phenomenon occurring between the second bonding structures 295.

An upper surface of the second shielding structures 245 may be coplanar with an upper surface of the second bonding structures 295. A height of the second shielding structure 245 in the vertical direction (Z-direction) may be less than a height of the second bonding structure 295 in the vertical direction (Z-direction). The height of the second shielding structure 245 in the vertical direction (Z-direction) may be a length from a lower surface of the second shielding structure 245 to the upper surface of the second shielding structure 245. The height of the second bonding structure 295 in the vertical direction (Z-direction) may be a length from a lower surface of the second bonding structure 295 to the upper surface of the second bonding structure 295. The lower surface of the second shielding structure 245 may be disposed on a higher level than the second insulating liner 232. The lower surface of the second shielding structure 245 may be disposed on a higher level than the lower surface of the second bonding structure 295. In an example, each of the second shielding structures 245 may have a width decreasing in a downward direction. The second shielding structures 245 may include the same metal material as the second bonding structures 295. For example, the second shielding structures 245 may include copper (Cu).

The second bonding insulating film 298 may surround upper regions of the second bonding structures 295 and upper regions of the second shielding structures 245. The second bonding insulating film 298 may expose upper surfaces of the second bonding structures 295 and upper surfaces of the second shielding structures 245. The upper surfaces of the second bonding insulating film 298, the upper surfaces of the second bonding structures 295, and the upper surfaces of the second shielding structures 245 may form a coplanar surface. The coplanar surface formed by the upper surfaces of the second bonding insulating film 298, the upper surfaces of the second bonding structures 295, and the upper surfaces of the second shielding structures 245 may face the coplanar surface formed by the lower surfaces of the first bonding insulating film 198, the lower surfaces of the first bonding structures 195, and the lower surfaces of the first shielding structures 145. In an example, the first bonding insulating film 198 and the second bonding insulating film 298 may include an oxide, a nitride, or an oxynitride.

The second intermediate insulating layer 221 may be disposed between the second insulating liner 232 and the second bonding insulating film 298. The second intermediate insulating layer 221 may surround side surfaces of the second bonding structures 295 and side surfaces of the second shielding structures 245. The second intermediate insulating layer 221 may include an insulating material, for example, silicon oxide. The second intermediate insulating layer 221 may include the same insulating material as the first intermediate insulating layer 231.

The second semiconductor structure 200 may further include second peripheral bonding structures 297 disposed in a peripheral region (e.g., peripheral region 200B of FIG. 2) and contacting the first peripheral bonding structures 197. The second peripheral bonding structures 297 may penetrate the second insulating liner 232 to the peripheral region to be connected to the second intermediate interconnection layer 227. The second peripheral bonding structures 297 may not be connected to the second intermediate interconnection layer 227, and may be disposed only for bonding. For example, the second peripheral bonding structures 297 may be electrically separated from the second intermediate interconnection layer 227. The second peripheral bonding structures 297 may have the same shape as the second bonding structure 295. The second bonding insulating film 298 extended to the peripheral region may surround upper regions of the second peripheral bonding structures 297. In an example, an upper surface of the second peripheral bonding structure 297 may be coplanar with an upper surface of the second bonding structure 295 and an upper surface of the second bonding insulating film 298. Side surfaces of the second peripheral bonding structures 297 may oppose each other. Shielding structures, such as the second shielding structures 245, may not be disposed between the second peripheral bonding structures 297.

The first semiconductor structure 100 and the second semiconductor structure 200 may be bonded by a hybrid bonding method. For example, the first bonding insulating film 198 and the second bonding insulating film 298 may be bonded by direct contact through a high-temperature annealing process, and may have a stronger bonding strength by covalent bonding of silicon and oxygen. For example, the first bonding insulating film 198 and the second bonding insulating film 298 may be bonded by a dielectric-dielectric bonding method.

The second semiconductor structure 200 may further include a first back insulating layer 231b on the lower surface (or fourth surface) of the second semiconductor substrate 210, and a third bonding insulating film 299 disposed on a lower surface of the first back insulating layer 231b. The first back insulating layer 231b may be in contact with the lower surface of the second semiconductor substrate 210, and may extend from a main region (e.g., main region 200A of FIG. 3) to a peripheral region (e.g., peripheral region 200B of FIG. 3). The third bonding insulating film 299 may be in contact with the lower surface of the first back insulating layer 231b, and may extend from the main region to the peripheral region, and a portion of the third bonding insulating film 299 may be in contact with a fourth bonding insulating film 399 of the third semiconductor structure 300. The first back insulating layer 231b may include an insulating material, for example, an oxide. The third bonding insulating film 299 may include an insulating material distinct from the first back insulating layer 231b, for example, a nitride or an oxide nitride.

A through-via hole VH may penetrate the second semiconductor substrate 210 in the vertical direction (Z-direction) in the peripheral region (e.g., peripheral region 200B of FIG. 3). The first back insulating layer 231b and the third bonding insulating film 299 may extend from the lower surface of the second semiconductor substrate 210 into the through-via hole VH, and may be in contact with a side wall of the through-via hole VH and a lower surface of the second interlayer insulating layer 231a exposed through the through-via hole VH.

A conductive through-via 247 may be disposed in the through-via hole VH. The conductive through-via 247 may penetrate the first back insulating layer 231b and the third bonding insulating film 299, and may be connected to the second intermediate interconnection layer 227. A lower surface of the conductive through-via 247 may be exposed from the third bonding insulating film 299. The conductive through-via 247 may include a metal material, for example, copper (Cu).

The third semiconductor structure 300 may be disposed below the second semiconductor structure 200. The third semiconductor structure 300 may include a third semiconductor substrate 310, a third interlayer insulating layer 321 on the third semiconductor substrate 310, a lower interconnection layer 327 disposed in the third interlayer insulating layer 321, a conductive pad 347, and a fourth bonding insulating film 399 surrounding upper regions of the conductive pad 347.

Logic circuit elements 350 may be disposed on an upper surface of the third semiconductor substrate 310 in an active region defined by an element isolation pattern ISOb. The logic circuit elements 350 may include an ADC circuit 13a.

Each of the logic circuit elements 350 may include a gate electrode 355, a gate insulating film 351 between the gate electrode 355 and the third semiconductor substrate 310, and source/drain regions 352 doped with impurities on both sides of the gate electrode 355. A third interlayer insulating film 321a surrounding the logic circuit elements 350 may be disposed on the upper surface of the third semiconductor substrate 310.

The lower interconnection layer 327 disposed on the upper surface of the third semiconductor substrate 310 may be disposed in the third interlayer insulating layer 321. The third interlayer insulating layer 321 may be disposed on the third interlayer insulating film 321a, and may be in contact with an upper surface of the third interlayer insulating film 321a. The third interlayer insulating layer 321 may include an insulating material, for example, silicon oxide. The lower interconnection layer 327 may be connected to the logic circuit elements 350, and may include lower interconnection lines 323 and lower interconnection vias 325 connected to the lower interconnection lines 323 and the logic circuit elements 350.

The fourth bonding insulating film 399 may be disposed on the lower interconnection layer 327, and may be in contact with the third bonding insulating film 299 of the second semiconductor structure 200. The fourth bonding insulating film 399 may extend from a main region (e.g., main region 300A of FIG. 3) to a peripheral region (e.g., peripheral region 300B of FIG. 3), and may surround an upper region of the conductive pad 347 disposed in the peripheral region.

The conductive pad 347 may be in contact with the conductive through-via 247 of the second semiconductor structure 200. The conductive pad 347 may include a metal material, for example, copper (Cu).

FIGS. 5A to 5G are enlarged views illustrating portion A of the image sensor of FIG. 4 according to embodiments.

FIG. 5A is an enlarged view illustrating portion A of the image sensor of FIG. 4 according to an embodiment. Referring to FIG. 5A, a first bonding structure 195 of a first semiconductor structure 100 may include a first portion (or, first plug portion) 195a having a first side surface, a second portion (or, first connection portion) 195b including a second side surface RS extending from the first side surface, and a third portion (or, first pad portion) 195c having a third side surface extending from the second side surface RS.

The first portion 195a may penetrate a first insulating liner 132, and may be connected to a first upper interconnection line 122. The first portion 195a may be a pillar portion, and may have a first width Wa.

The second portion 195b may have the second side surface RS extending from the first side surface of the first portion 195a and having a width non-linearly increasing in a downward direction. The first side surface of the first portion 195a and the second side surface RS of the second portion 195b may be non-linearly connected. The second portion 195b may correspond to a portion having a side surface of which width increases from the first width Wa of the first portion 195a to a third width Wc of the third portion 195c. In an example, the second side surface RS of the second portion 195b may have a concave side surface.

The third portion 195c may have the third side surface extending from the second side surface RS of the second portion 195b, and may have a pad shape having the third width Wc, which may be constant.

In an embodiment, the third width Wc of the third portion 195c may be greater than the first width Wa of the first portion 195a. For example, the first width Wa may be about 117 nm, and the third width Wc may be about 410 nm. In an example, the second portion 195b may have a second width Wb that may be between the first width Wa of the first portion 195a and the third width Wc of the third portion 195c. The second width Wb of the second portion 195b may be greater than the first width Wa and less than the third width Wc. For example, the width of the second portion 195b may gradually increase from about 138 nm to about 400 nm in a downward direction.

The lower surface of the first bonding insulating film 198, the lower surface of the first bonding structures 195, and the lower surface of the first shielding structures 145 may form a coplanar surface. The first shielding structures 145 may be disposed between the first bonding structures 195. A height of each of the first shielding structures 145 in the vertical direction (Z-direction) may be less than a height of each of the first bonding structures 195 in the vertical direction (Z-direction). For example, a length from the lower surface of the first shielding structure 145 to the upper surface of the first shielding structure 145 may be greater than a length from the lower surface of the first bonding insulating film 198 to the upper surface of the first bonding insulating film 198. In an example, the first shielding structure 145 may overlap the second and third portions (195b, 195c) of the adjacent first bonding structures 195 in a horizontal direction, and may not overlap the first portion 195a of the first bonding structures 195 in a horizontal direction. In an example, the height of the first shielding structure 145 in the vertical direction (Z-direction) may be equal to a first height H1, which may be a length from the lower surface of the first bonding structure 195 to an upper end of the second portion 195b. In an example, the first height H1 may be about 430 nm.

The first bonding insulating film 198 may surround most of lower regions of side surfaces of the third portions 195c of the first bonding structures 195.

A height from the lower surface of the first bonding insulating film 198 to the upper surface of the first bonding insulating film 198 may be less than a second height H2, which may be a length from the lower surface of the first bonding structure 195 to an upper end of the third portion 195c. The length from the lower surface of the first shielding structure 145 to the upper surface of the first shielding structure 145, which may be a height of the first shielding structure 145, may be greater than the second height H2.

The second bonding structure 295 and the second shielding structure 245 may be identically applied to the description of the first bonding structure 195 and the first shielding structure 145, described above with reference to FIG. 5A. The second bonding structure 295 may have a shape that is symmetrical with respect to the first bonding structure 195, based on the X-axis.

The second bonding structure 295 of the second semiconductor structure 200 may include a fourth portion (or, second plug portion) 295a having a fourth side surface, a fifth portion (or, second connection portion) 295b having a fifth side surface extending from the fourth side surface and having a width increasing in an upward direction, and a sixth portion (or, second pad portion) 295c having a sixth side surface extending from the fifth side surface.

The first semiconductor structure 100 may further include a first bonding barrier film 196 surrounding a side wall of the first bonding structure 195 and an upper surface of the first portion 195a, and a first shield barrier film 146 surrounding a side wall and the upper surface of the first shielding structure 145.

The second semiconductor structure 200 may further include a second bonding barrier film 296 surrounding a side wall of the second bonding structure 295 and a lower surface of the fourth portion 295a, and a second shield barrier film 246 surrounding a side wall and the lower surface of the second shielding structure 245. In an example, the first and second bonding barrier films 196 and 296 and the first and second shield barrier films 146 and 246 may include Ta, TaN, Mn, MnN, WN, Ti, TiN, or a combination thereof.

FIG. 5B is an enlarged view illustrating portion A of the image sensor of FIG. 4 according to an embodiment. Referring to FIG. 5B, remaining configurations except for first and second bonding structures 195′ and 295′ may be identical or correspond to the configurations illustrated in FIG. 5A.

A first bonding structure 195′ of a first semiconductor structure 100 may include a first portion 195a′ having a first side surface, a second portion 195b′ extending from the first portion 195a′, and a third portion 195c′ extending from the second portion 195b′.

The first portion 195a′ may penetrate a first insulating liner 132 to be connected to a first upper interconnection line 122.

The second portion 195b′ may include an upper surface FSa extending from the first portion 195a′, and a second side surface RSa extending from the upper surface FSa and having a width increasing in a downward direction. The upper surface FSa may be a stepped surface between the first portion 195a′ and the second portion 195b′. For example, the upper surface FSa may extend horizontally between the first portion 195a′ and the second portion 195b′. In an example, a width of the first portion 195a′ may be less than a width of the upper surface FSa of the second portion 195b′.

The third portion 195c′ may be a pad shape having a third side surface extending from the second side surface RSa of the second portion 195b′.

The first semiconductor structure 100 may further include a first bonding barrier film 196′ surrounding side walls of the first and third portions 195a′ and 195c′ of the first bonding structure 195′, the second side surface RSa and the upper surface FSa of the second portion 195b′, and an upper surface of the first portion 195a′.

A second semiconductor structure 200 may further include a second bonding barrier film 296′ surrounding side walls of fourth and sixth portions 295a′ and 295c′ of a second bonding structure 295′, side and lower surfaces of the fifth portion (295b′), and a lower surface of the fourth portion 295a′.

FIG. 5C is an enlarged view illustrating portion A of the image sensor of FIG. 4 according to an embodiment. Referring to FIG. 5C, remaining configurations except for first and second shielding structures 145′ and 245′ may be identical or correspond to the configurations illustrated in FIG. 5A.

A first shielding structures 145′ may be disposed between first bonding structures 195. A height of each of the first shielding structures 145′ in the vertical direction (Z-direction) may be less than a first height H1, which may be a length from a lower surface of the first bonding structure 195 to an upper end of a second portion 195b. In an example, a height from a lower surface of the first shielding structure 145′ to an upper surface of the first shielding structure 145′ may be equal to a second height H2, which may be a length from the lower surface of the first bonding structure 195 to an upper end of a third portion 195c. The first shielding structure 145′ may overlap the third portion 195c of the first bonding structure 195, adjacent thereto, in a horizontal direction, and may not overlap a first portion 195a and the second portion 195b of the first bonding structures 195 in a horizontal direction. In another embodiment, the height of each of the first shielding structures 145′ in the vertical direction (Z-direction) may be less than the first height H1, which may be the length from the lower surface of the first bonding structure 195 to the upper end of the second portion 195b, and in this case, may be greater than the second height H2, which may be the length from the lower surface of the first bonding structure 195 to the upper end of the third portion 195c. The first shielding structure 145′ may overlap a portion of the third portion 195c and a portion of the second portion 195b of the first bonding structure 195, adjacent thereto, in a horizontal direction.

A first semiconductor structure 100 may further include a first shield barrier film 146′ surrounding a side wall and an upper surface of the first shielding structure 145′, and a second semiconductor structure 200 may further include a second shield barrier film 246′ surrounding a side wall and a lower surface of a second shielding structure 245′.

FIG. 5D is an enlarged view illustrating portion A of the image sensor of FIG. 4 according to an embodiment. Referring to FIG. 5D, remaining configurations except for first and second shielding structures 145″ and 245″ may be identical or correspond to the configurations illustrated in FIG. 5A.

First shielding structures 145″ may be disposed between first bonding structures 195. A height of each of the first shielding structures 145″ in the vertical direction (Z-direction) may be less than a height from a lower surface of the first bonding structure 195 to an upper surface of the first bonding structure 195, and may be greater than a first height H1, which may be a length from a lower surface of the first bonding structure 195 to an upper end of a second portion 195b.

The first shielding structure 145″ may not only overlap the second portion 195b and the third portion 195c of the first bonding structure 195, adjacent thereto, in a horizontal direction, but may also overlap a portion of a first portion 195a in a horizontal direction, and may not overlap a remaining portion of the first portion 195a of the first bonding structures 195 in a horizontal direction.

A first semiconductor structure 100 may further include a first shield barrier film 146″ surrounding a side wall and an upper surface of the first shielding structure 145″, and a second semiconductor structure 200 may further include a second shield barrier film 246″ surrounding a side wall and a lower surface of a second shielding structure 245″.

FIG. 5E is an enlarged view illustrating portion A of the image sensor of FIG. 4 according to an embodiment. Referring to FIG. 5E, remaining configurations except for first and second bonding structures 195″ and 295″ may be identical or correspond to the configurations illustrated in FIG. 5A.

A first bonding structure 195″ of a first semiconductor structure 100 may include a first portion 195a″ having a first side surface, a second portion 195b″ having a second side surface RS extending from the first side surface and having a width increasing in a downward direction, and a third portion 195c″ extending from the second side surface RS.

A second height H2′, which may be a length from a lower surface of the first bonding structure 195″ to an upper end of the third portion 195c″, may be greater than a third height H3 of a first bonding insulating film 198, which may be a length from a lower surface of the first bonding insulating film 198 to an upper surface of the first bonding insulating film 198. In an example, the second height H2′ may be about twice as long as the third height H3. The first bonding insulating film 198 may surround about half (i.e., a lower half) of a side surface of the third portion 195c″ of the first bonding structure 195″.

The first semiconductor structure 100 may further include a first bonding barrier film (196″) surrounding a side wall of the first bonding structure 195″ and an upper surface of the first portion 195a″, and a second semiconductor structure 200 may further include a second bonding barrier film 296″ surrounding a side wall of a second bonding structure 295″ and a lower surface of a fourth portion 295a″.

FIG. 5F is an enlarged view illustrating portion A of the image sensor of FIG. 4 according to an embodiment. Referring to FIG. 5F, remaining configurations except for first and second bonding insulating films 198′ and 298′ may be identical or correspond to the configurations illustrated in FIG. 5E.

A majority of a side surface of a third portion 195c″ of a first bonding structure 195″ may be exposed from a first bonding insulating film 198′. A majority of a side surface of a third portion 295c″ of a second bonding structure 295″ may be exposed from a second bonding insulating film 298′. A second height H2′, which may be a length from a lower surface of the first bonding structure 195″ to an upper end of the third portion 195c″, may be greater than a third height H3′ of the first bonding insulating film 198′. For example, the second height H2′ may be about three times the third height H3′.

FIG. 5G is an enlarged view illustrating portion A of the image sensor of FIG. 4 according to an embodiment. Referring to FIG. 5G, remaining configurations except for first and second bonding structures 195_1 and 295_1 and first and second shielding structures 145_1 and 245_1 may be identical or correspond to the configurations illustrated in FIG. 5A.

A first bonding structure 195_1 of a first semiconductor structure 100 may include a first portion 195a_1 having a first side surface, a second portion 195b_1 extending from the first portion 195a_1, and a third portion 195c_1 extending from the second portion 195b_1.

The first portion 195a_1 may penetrate a first insulating liner 132 to be connected to a first upper interconnection line 122.

The second portion 195b_1 may include an upper surface FSb extending from the first portion 195a_1, and a second side surface RSb extending from the upper surface FSb and having a width increasing in a downward direction. The upper surface FSb may be a stepped surface between the first portion 195a_1 and the second portion 195b_1. For example, the upper surface FSb may extend horizontally between the first portion 195a_1 and the second portion 195b_1. In an example, a first width Wa′ of the first portion 195a_1 may be less than a second width Wb′ that may be a width of an upper end portion of the second portion 195b_1. For example, the first width Wa′ may be about 135 nm. The second width Wb′ may be about 210 nm. The second side surface RSb may be a concave surface.

The third portion 195c_1 may have a third side surface RSc extending from the second side surface RSb of the second portion 195b_1 and having a width increasing in a downward direction. The third side surface RSc may be a convex surface. A fourth width Wd′, which may be a maximum width of the third portion 195c_1, may be about 520 nm.

At a point in which the second side surface RSb of the second portion 195b_1 and the third side surface RSc of the third portion 195c_1 meet, the first bonding structure 195_1 may have a third width Wc′. For example, a third width Wc′ may be about 460 nm. The second portion 195b_1 may gradually increase in width from about 210 nm to about 460 nm in a downward direction.

A height from a lower surface of the first bonding structure 195_1 to an upper surface of the first bonding structure 195_1 may be about 630 nm. A first height H1″, which may be a length from the lower surface of the first bonding structure 195_1 to an upper end portion of the second portion 195b_1, may be about 430 nm. A second height H2″, which may be a length from the lower surface of the first bonding structure 195_1 to an upper end portion of the third portion 195c_1, may be about 250 nm.

First shielding structures 145_1 may be disposed between the first bonding structures 195_1. A height from a lower surface of a first shielding structure 145_1 to an upper surface of the first shielding structure 145_1 may be less than the second height H2″, which may be a length from the lower surface of the first bonding structure 195_1 to the upper end portion of the third portion 195c_1. The height from the lower surface of the first shielding structure 145_1 to the upper surface of the first shielding structure 145_1 may be greater than a height of a first bonding insulating film 198.

The first semiconductor structure 100 may include a first bonding barrier film 196_1 and a first shield barrier film 146_1. The first bonding barrier film 196_1 may surround side walls of the first and third portions 195a_1 and 195c_1 of the first bonding structure 195_1, the second side surface RSb and the upper surface FSb of the second portion 195b_1, and an upper surface of the first portion 195a_1. The first shield barrier film 146_1 may surround a side wall and an upper surface of the first shielding structure 145_1.

The second semiconductor structure 200 may include a second bonding barrier film 296_1 and a second shield barrier film 246_1. The second bonding barrier film 296_1 may surround side walls of fourth and sixth portions 295a_1 and 295c_1 of a second bonding structure 295_1, side and stepped surfaces of a fifth portion 295b_1, and a lower surface of the fourth portion 295a_1. The second shield barrier film 246_1 may surround a side wall and a lower surface of a second shielding structure 245_1.

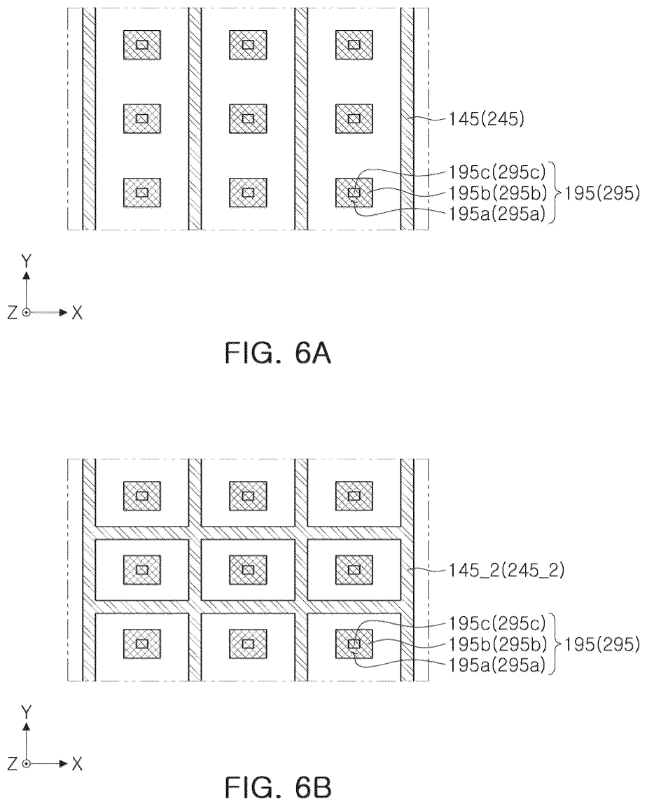

FIGS. 6A and 6B are plan views schematically illustrating bonding structures (i.e., first and second bonding structures) and shielding structures (i.e., first and second shielding structures) of the image sensor of FIG. 4, according to embodiments.

FIG. 6A illustrates a planar arrangement relationship between first bonding structures 195 (or second bonding structures 295 which have a planar arrangement that corresponds to that of the first bonding structures 195) and first shielding structures 145 (or second shielding structures 245 which have a planar arrangement that corresponds to that of the first shielding structures 145).

Referring to FIG. 6A, first bonding structures 195 may have a planar shape of a tetragon, respectively, but are not limited thereto, and each of the first bonding structures 195 may have various planar shapes such as a circle, an ellipse, a polygon, or the like.

The first bonding structures 195 may be provided in plural. The first bonding structures 195 may be disposed in the first direction (X-direction) and the second direction (Y-direction). The first bonding structure 195 may overlap a second bonding structure 295 in the vertical direction (Z-direction). In a first bonding structure 195, a first portion 195a and a third portion 195c may overlap in the vertical direction (Z-direction), and a second portion 195b may connect the first portion 195a and the third portion 195c between the first portion 195a and the third portion 195c. A width of the first portion 195a may be constant and a width of the third portion 195c may be constant. A width of the second portion 195b may decrease toward to the first portion 195a, and conversely, may increase toward the third portion 195c.

First shielding structures 145 may be disposed between first bonding structures 195 adjacent to each other in the first direction (X-direction). In an example, second shielding structures 245 may be disposed between second bonding structures 295 adjacent to each other in the first direction (X-direction). The first and second shielding structures 145 and 245 may extend in the second direction (Y-direction).

FIG. 6B illustrates a planar arrangement relationship between first bonding structures 195 (or second bonding structures 295 which have a planar arrangement that corresponds to that of the first bonding structures 195) and first shielding structures 145_2 (or second shielding structures 245_2 which have a planar arrangement that corresponds to that of the first shielding structures 145_2). Referring to FIG. 6B, remaining configurations except for first and second shielding structures 145_2 and 245_2 may be identical or correspond to the configurations illustrated in FIG. 6A.

In a X-Y plane, the first shielding structure 145_2 may surround first bonding structures 195. The second shielding structures 245_2 may surround second bonding structures 295. The first and second shielding structures 145_2 and 245_2 may have a mesh shape, respectively. The first and second shielding structures 145_2 and 245_2 may extend in the first direction (X-direction) and the second direction (Y-direction).

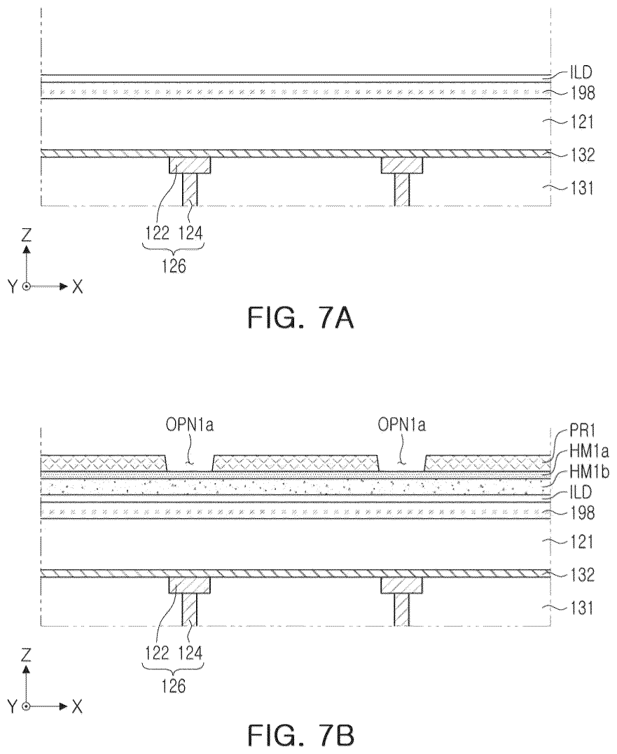

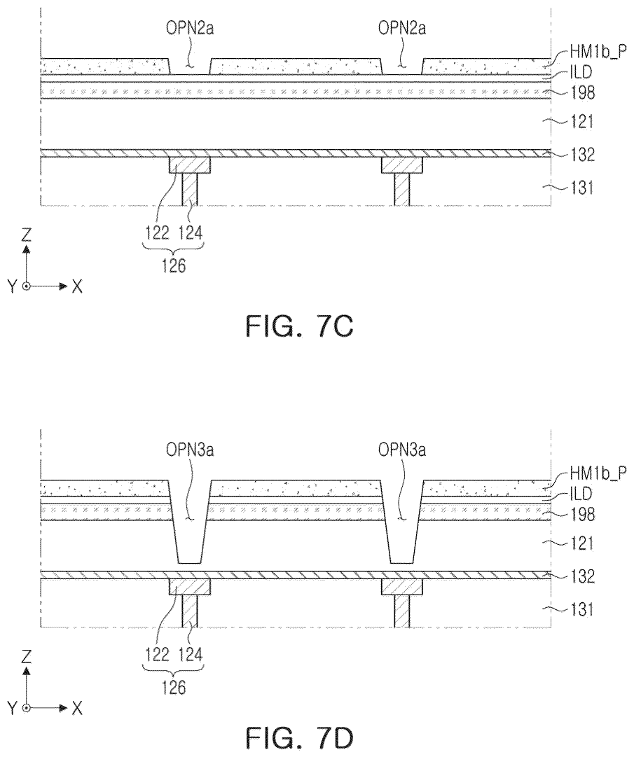

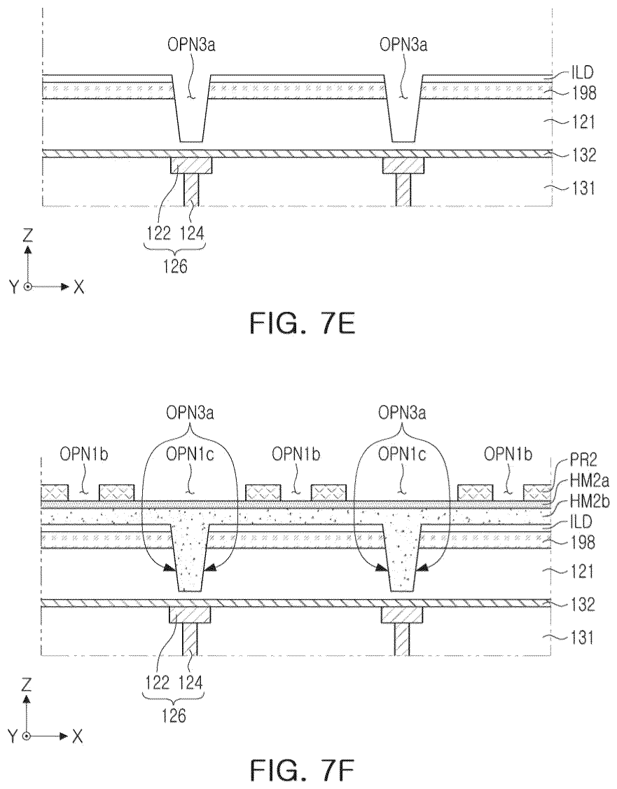

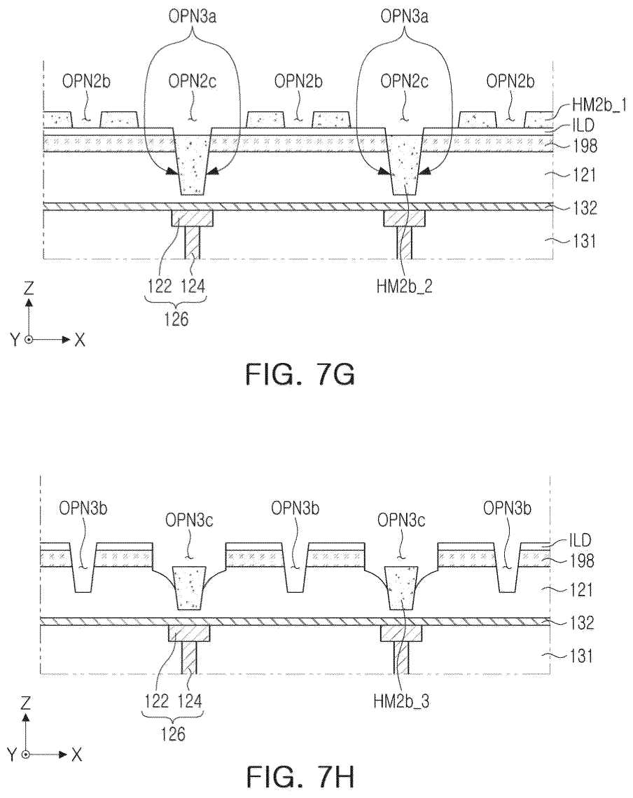

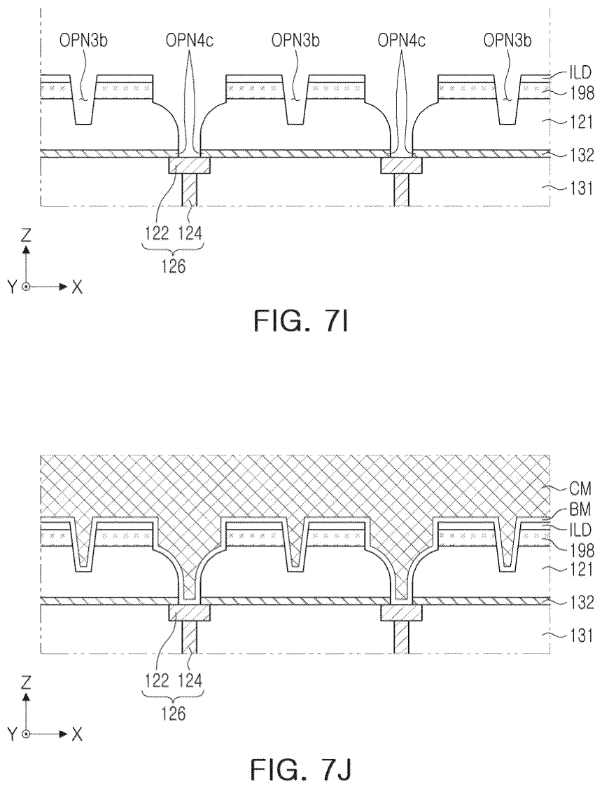

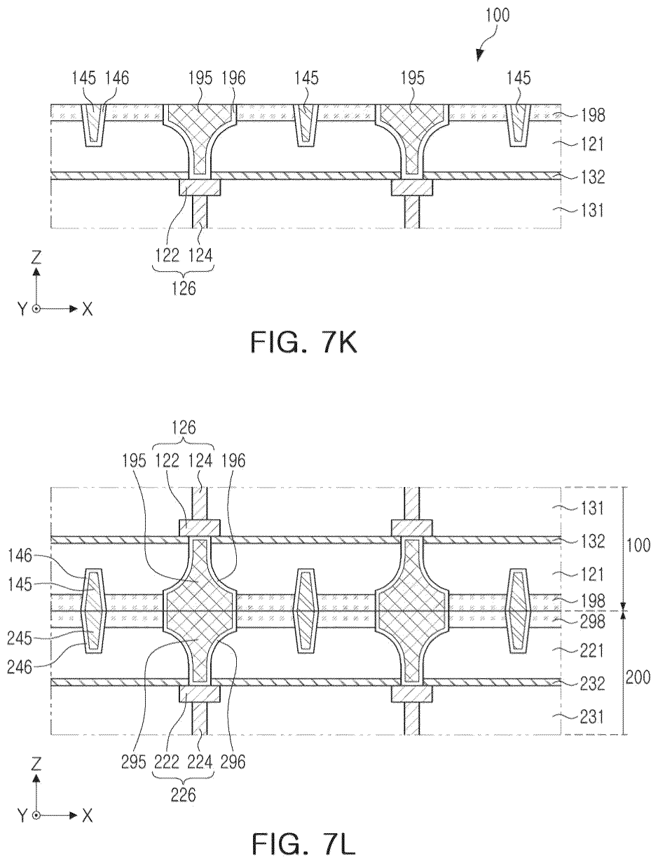

FIGS. 7A to 7L are cross-sectional views of forming first bonding structures and first shielding structures according to a manufacturing method according to an embodiment.

Referring to FIG. 4 and FIG. 7A, a first semiconductor substrate 110, as in FIG. 4, may be provided. Pixel isolation structures 180 penetrating the first semiconductor substrate 110, photodiodes PD between the pixel isolation structures 180, transfer transistors TX and floating diffusion nodes FD in the first semiconductor substrate 110, on a front surface of the first semiconductor substrate 110, forming color filters CF and micro lenses ML may be formed on the back side of the first semiconductor substrate 110. A first upper insulating layer 131 and a first upper interconnection layer 126 may be formed on the front surface of the first semiconductor substrate 110. A process of forming first bonding structures 195 and first shielding structures 145 may be performed. The forming the first upper insulating layer 131 and the first upper interconnection layer 126 may include forming the first upper insulating layer 131 on the front surface of the first semiconductor substrate 110, and forming the first upper interconnection layer 126 connected to a floating diffusion node FD in the first upper insulating layer 131.

Referring to FIG. 7A, a first insulating liner 132, a second upper insulating layer 121, a first bonding insulating film 198, and a protective insulating layer ILD may be sequentially formed in the vertical direction (Z-direction) on a first upper interconnection layer 126 and first upper insulating layer 131. The first insulating liner 132 may be an etch stop layer for protecting the first upper interconnection layer 126.

Referring to FIG. 7B, first hard mask material layers HM1a and HM1b, and a first photoresist pattern PR1 may be sequentially formed on the protective insulating layer ILD. The first hard mask material layers HM1a and HM1b may include a 1-1 hard mask material layer HM1b formed on the protective insulating layer ILD and a 1-2 hard mask material layer HM1a formed on the 1-1 hard mask material layer HM1b. The first photoresist pattern PR1 may be formed on the 1-2 hard mask material layer HM1a.

The first photoresist pattern PR1 may be formed by performing an exposure and development process after forming a photoresist film. The first photoresist pattern PR1 may be used as an etching mask for the first hard mask material layers HM1a and HM1b.

In an example, the 1-1 hard mask material layer HM1b may include a spin-on hardmask (SOH), an amorphous carbon layer (ACL), or the like. The 1-2 hard mask material layer HM1a may include a silicon oxide film, a silicon nitride film, or a silicon oxynitride film. The first hard mask material layers HM1a and HM1b may be formed by, for example, a plasma enhanced chemical vapor deposition (PECVD) process.

The first photoresist pattern PR1 may include define openings OPN1a. Positions of the first openings OPN1a may correspond to first upper interconnection layers 126.

In an example, the first openings OPN1a may overlap the first upper interconnection layers 126 in the vertical direction (Z-direction). Positions of the first openings OPN1a may define a region in which first bonding structures (e.g., first bonding structures 195 of FIG. 4) are to be formed.

Referring to FIG. 7C, by using the first photoresist pattern PR1 of FIG. 7B as an etching mask, the first hard mask material layers HM1a and HM1b may be etched to form a first hard mask pattern HM1b_P. The first hard mask pattern HM1b_P may include second openings OPN2a corresponding to the first openings OPN1a of the first photoresist pattern PR1. The second openings OPN2a may overlap the first openings OPN1a in the vertical direction. In a process of etching the first hard mask material layers HM1a and HM1b, the 1-2 hard mask material layers HM1a may be removed, and a portion of an upper surface of the protective insulating layer ILD overlapping the second openings OPN2a may be exposed.

Referring to FIG. 7D, by using the first hard mask pattern HM1b_P as a mask, an etching process may be performed to remove a portion of the first bonding insulating film 198, a portion of the second upper insulating layer 121, and a portion of the protective insulating layer ILD located on a bottom surface of the second openings OPN2a of the first hard mask pattern HM1b_P, thereby forming third openings OPN3a. A side wall of the protective insulating layer ILD, a side wall of the first bonding insulating film 198, and a side wall and a bottom surface of the second upper insulating layer 121 may be exposed through the third openings OPN3a.

Referring to FIG. 7E, the first hard mask pattern HM1b_P on the protective insulating layer ILD may be removed.

Referring to FIG. 7F, second hard mask material layers HM2a and HM2b and a second photoresist pattern PR2 may be sequentially formed on the protective insulating layer ILD on which the third openings OPN3a are formed. The second hard mask material layers HM2a and HM2b may fill the third openings OPN3a, and may include a 2-1 hard mask material layer HM2b formed on the protective insulating layer ILD, and a 2-2 hard mask material layer HM2a formed on the 2-1 hard mask material layer HM2b. The second photoresist pattern PR2 may be formed on the 2-2 hard mask material layer HM2a. In an example, the 2-1 hard mask material layer HM2b may be formed to fill the third openings OPN3a of FIG. 7E, and may cover the protective insulating layer ILD. An upper surface of the 2-1 hard mask material layer HM2b may be flat. The 2-2 mask material layer HM2a and the second photoresist pattern PR2 may be formed on the 2-1 mask material layer HM2b.

The second photoresist pattern PR2 may be formed by performing an exposure and development process after forming a photoresist film. The second photoresist pattern PR2 may be used as an etching mask for the second hard mask material layers HM2a and HM2b.

The second photoresist pattern PR2 may include 1-1 openings OPN1b and 1-2 openings OPN1c. Positions of the 1-1 openings OPN1b may define a region in which first shielding structures (e.g., first shielding structures 145 of FIG. 4) are to be formed. Positions of the 1-2 openings OPN1c may correspond to the first upper interconnection layers 126 and the third openings OPN3a of FIG. 7E. The 1-2 openings OPN1c may be spaced apart from the 1-1 openings OPN1b in a horizontal direction.

Referring to FIG. 7G, by using the second photoresist pattern PR2 as an etching mask, the second hard mask material layers HM2a and HM2b may be etched to form a second hard mask pattern HM2b_1 and a first dummy hard mask patterns HM2b_2. The second hard mask pattern HM2b_1 may include 2-1 openings OPN2b corresponding to the 1-1 openings OPN1b of the second photoresist pattern PR2, and 2-2 openings OPN2c corresponding to the 1-2 openings OPN1c of the second photoresist pattern PR2. The first dummy hard mask patterns HM2b_2 may fill a side wall of the first bonding insulating film 198 and a side wall and a bottom surface of the second upper insulating layer 121, forming the third opening portions OPN3a. In a process of etching the second hard mask material layers HM2a and HM2b, the 2-2 hard mask material layer HM2a may be removed, and the 2-1 hard mask material layer HM2b surrounding a side wall of the protective insulating layer ILD forming the third openings OPN3a may be removed, to expose the side wall of the protective insulating layer ILD and an upper surface of the first dummy hard mask patterns HM2b_2 through the 2-2 openings OPN2c. The first dummy hard mask pattern HM2b_2 may overlap the 2-2 openings OPN2c in the vertical direction (Z-direction).

Referring to FIG. 7H, by using the second hard mask pattern HM2b_1 and the first dummy hard mask pattern HM2b_2 as masks, a portion of the first bonding insulating film 198, a portion of the second upper insulating layer 121, and a portion of the protective insulating layer ILD located on bottom surfaces of the 2-1 openings OPN2b and the 2-2 openings OPN2c may be removed to form 3-1 openings OPN3b and 3-2 openings OPN3c.

The portion of the first bonding insulating film 198, the portion of the second upper insulating layer 121, and the portion of the protective insulating layer ILD located on the bottom surfaces of the 2-1 openings OPN2b may be removed to form the 3-1 openings OPN3b. Through the 3-1 openings OPN3b, a side surface of the protective insulating layer ILD, a side surface of the first bonding insulating film 198, side and bottom surfaces of the second upper insulating layer 121 may be exposed.

Portions of the first dummy hard mask patterns HM2b_2 located on the bottom surface of the 2-2 openings OPN2c of FIG. 7G may be removed to lower a vertical height of the first dummy hard mask patterns HM2b_2, thereby forming second dummy hard mask patterns HM2b_3. The protective insulating layer ILD and the first bonding insulating film 198 overlapping the bottom surface of the 2-2 openings OPN2c may be removed. The first dummy hard mask patterns HM2b_2 of FIG. 7G may have etching selectivity with respect to the protective insulating layer ILD, the first bonding insulating film 198, and the second upper insulating layer 121. Therefore, a portion of the second upper insulating layer 121 adjacent to the second dummy hard mask patterns HM2b_3 may be removed to form the 3-2 openings OPN3c. Therefore, the portion of the second upper insulating layer 121 removed in the vertical direction (Z-direction) may decrease toward the second dummy hard mask patterns HM2b_3.

Referring to FIG. 7I, the second dummy hard mask patterns HM2b_3 may be removed, and the second upper insulating layer 121 and the first insulating liner 132 overlapping bottom surfaces of the second dummy hard mask patterns HM2b_3 may be removed to form fourth openings OPN4c. Therefore, the first upper interconnection layer 126 formed below the first insulating liner 132 may be exposed through the fourth openings OPN4c.

Referring to FIG. 7J, a preliminary conductive barrier layer BM and a preliminary buried conductive layer CM may be formed on an upper surface of the protective insulating layer ILD, the 3-1 openings OPN3b, and the fourth openings OPN4c. The preliminary conductive barrier layer BM may be formed by uniformly depositing a conductive material on the upper surface of the protective insulating layer ILD, an entire surface of the 3-1 openings OPN3b, and an entire surface of the fourth openings OPN4c. The preliminary buried conductive layer CM may fill the 3-1 openings OPN3b and the fourth openings OPN4c on the preliminary conductive barrier layer BM, and may cover the upper surface of the protective insulating layer ILD.

Referring to FIG. 7K, an etch-back process may be performed on the preliminary buried conductive layer CM, the preliminary conductive barrier layer BM, and the protective insulating layer ILD to expose the upper surface of the first bonding insulating film 198, thereby forming first bonding structures 195 connected to the first upper interconnection layer 126, and first shielding structures 145 between the first bonding structures 195. Therefore, the first semiconductor structure 100 of FIG. 4 may be manufactured.

Referring to FIG. 7L, the first bonding structures 195 of the first semiconductor structure 100 may be flipped over to be disposed below the first upper interconnection layer 126, and the first bonding insulating film 198, the first bonding structures 195, and the first shielding structures 145 of the first semiconductor structure 100 may be bonded to a second bonding insulating film 298, second bonding structures 295, and second shielding structures 245 of a second semiconductor structure 200.

Prior to a process of bonding the first semiconductor structure 100 and the second semiconductor structure 200, the second semiconductor structure 200 may be manufactured. Referring to FIG. 4, a method of forming the second semiconductor structure 200 may include preparing a second semiconductor substrate 210, forming pixel circuit elements 250 on an upper surface of the second semiconductor substrate 210, forming a first intermediate insulating layer 231 and a second interconnection structure (226 and 227) connected to the pixel circuit elements 250 on the second semiconductor substrate 210, forming a second insulating liner 232 on the second interconnection structure (226 and 227), and forming second shielding structures 245 and second bonding structures 295 penetrating the second insulating liner 232 on the second interconnection structure (226 and 227). A method of forming the second bonding structures 295 and the second shielding structures 245 may correspond to the method of forming the first bonding structures 195 and the first shielding structures 145 of the first semiconductor structure 100, described above with reference to FIGS. 7A to 7K.

In an image sensor including first and second semiconductor structures including elements constituting a plurality of pixels and a third semiconductor structure including logic circuit elements, according to embodiments, the image sensor may include bonding structures connecting the first and second semiconductor structures, and each of the bonding structures may include a plug portion, a pad portion, and a connection portion having a side surface extending from a side surface of the plug portion and a side surface of the pad portion and having a width increasing toward the pad portion. Therefore, occurrence of a void occurring in a process of filling a metal material in the plug portion and the pad portion may be minimized and/or improved.

In addition, the image sensor may include shielding structures disposed between the bonding structures, thereby minimizing a coupling phenomenon that may occur between the bonding structures. Therefore, an image sensor having improved electrical characteristics may be provided.

Effects are not limited to the above-described effects, and may be variously expanded in a scope that does not depart from the spirit and scope of the present disclosure.

While aspects of example embodiments have been illustrated and described above, it will be apparent to those skilled in the art that modifications and variations could be made without departing from the scope of the present inventive concept as defined by the appended claims.

What is claimed is:

1. An image sensor comprising:
a first semiconductor structure comprising a first semiconductor substrate, a plurality of photodiodes in a first region of the first semiconductor substrate, a first interconnection structure below the first semiconductor substrate, first bonding structures below the first interconnection structure and connected to the first interconnection structure, first shielding structures between the first bonding structures, and a first bonding insulating film surrounding lower regions of the first bonding structures and lower regions of the first shielding structures;
a second semiconductor structure comprising a second semiconductor substrate, a second interconnection structure in the second semiconductor substrate, second bonding structures contacting the first bonding structures on the second interconnection structure and connected to the second interconnection structure, second shielding structures between the second bonding structures and contacting the first shielding structures, and a second bonding insulating film surrounding upper regions of the second bonding structures and upper regions of the second shielding structures; and
a third semiconductor structure comprising a third semiconductor substrate below the second semiconductor structure, and a third interconnection structure between the third semiconductor substrate and the second semiconductor structure, wherein the third interconnection structure is electrically connected to the second interconnection structure,
wherein each of the first bonding structures comprises a first portion connected to the first interconnection structure and having a first side surface, a second portion having a second side surface extending from the first side surface and having a width that increases with proximity to the second semiconductor structure, and a third portion having a third side surface extending from the second side surface and at least partially contacting the first bonding insulating film, and
wherein a first width of the first portion is less than a second width of the third portion.

2. The image sensor of claim 1, further comprising:
a first insulating liner on a lower surface of the first interconnection structure; and
a first interlayer lower insulating layer between the first insulating liner and the first bonding insulating film,
wherein the first portion of each of the first bonding structures penetrates the first insulating liner, and is connected to the first interconnection structure.

3. The image sensor of claim 2, wherein an upper surface of each of the first shielding structures is closer to the second semiconductor structure than the first insulating liner.

4. The image sensor of claim 1, wherein the second side surface of the second portion of each of the first bonding structures has a concave shape.

5. The image sensor of claim 1, wherein a height from a lower surface of the first shielding structures to an upper surface of the first shielding structures is greater than a height from a lower surface of the third portion to the second portion in each of the first bonding structures.

6. The image sensor of claim 1, wherein the first semiconductor structure further comprises a floating diffusion node in the first semiconductor substrate,
wherein the second semiconductor structure further comprises a source follower transistor on the second semiconductor substrate,
wherein the floating diffusion node is connected to a first interconnection layer of the first interconnection structure and each of the first bonding structures connected to the first interconnection layer, and
wherein a gate electrode of the source follower transistor is connected to a second interconnection layer of the second interconnection structure and each of the second bonding structures connected to the second interconnection layer.

7. The image sensor of claim 1, further comprising:
a first bonding barrier film on a side wall and an upper surface of each of the first bonding structures; and
a first shield barrier film on a side wall and an upper surface of each of the first shielding structures.

8. The image sensor of claim 1, wherein the first semiconductor substrate has a second region surrounding the first region,
wherein the first bonding structures vertically overlap the first region of the first semiconductor substrate,
wherein the first semiconductor structure further comprises third bonding structures connected to the first interconnection structure and overlapping the second region of the first semiconductor substrate, and
wherein the first shielding structures are not between the third bonding structures.

9. The image sensor of claim 1, wherein a height of the first bonding insulating film in a vertical direction is less than a height of the third portion of each of the first bonding structures in the vertical direction.

10. The image sensor of claim 1, wherein a width of the second portion of each of the first bonding structures non-linearly increases as proximity to the second semiconductor structure increases.

11. The image sensor of claim 1, wherein each of the second bonding structures comprises a fourth portion connected to the second interconnection structure and having a fourth side surface, a fifth portion having a fifth side surface extending from the fourth side surface and having a width increasing as proximity to the second semiconductor structure decreases, and a sixth portion having a sixth side surface extending from the fifth side surface and contacting the third portion of each of the first bonding structures and at least partially contacting the second bonding insulating film.

12. The image sensor of claim 11, further comprising:
a second insulating liner on an upper surface of the second interconnection structure; and
a second interlayer upper insulating layer between the second insulating liner and the second bonding insulating film,
wherein the fourth portion of each of the second bonding structures penetrates the second insulating liner and is connected to the second interconnection structure.

13. An image sensor comprising:
a first semiconductor structure comprising a first semiconductor substrate having a first surface and a second surface opposite to the first surface, photodiodes in the first semiconductor substrate, first to third pixel isolation structures spaced apart from each other in the first semiconductor substrate and defining regions in which the photodiodes are provided, color filters on the first surface of the first semiconductor substrate, a first interconnection structure below the second surface, a first insulating liner on a lower surface of the first interconnection structure, first and second upper bonding structures penetrating the first insulating liner and connected to the first interconnection structure, and a first shielding structure between the first and second upper bonding structures; and
a second semiconductor structure comprising a second semiconductor substrate having a third surface and a fourth surface opposite to the third surface, a second interconnection structure on the third surface of the second semiconductor substrate, a second insulating liner on the second interconnection structure, first and second intermediate bonding structures respectively contacting the first and second upper bonding structures penetrating the second insulating liner and connected to the second interconnection structure, and a second shielding structure between the first and second intermediate bonding structures and contacting the first shielding structure,
wherein the first upper bonding structure overlaps a first region of the first semiconductor substrate,
wherein a first photodiode among the photodiodes is in the first region of the first semiconductor substrate between the first pixel isolation structure and the second pixel isolation structure,
wherein the second upper bonding structure overlaps a second region of the first semiconductor substrate in which a second photodiode among the photodiodes is provided between the second pixel isolation structure and the third pixel isolation structure, and
wherein each of the first and second upper bonding structures comprises a plug portion contacting the first interconnection structure and having a first width, an extension portion extending from the plug portion in a downward direction and having a width that increases along the downward direction, and a pad portion extending from the extension portion in the downward direction and having a second width, greater than the first width.

14. The image sensor of claim 13, wherein the first semiconductor structure further comprises:
a first floating diffusion node in the first region of the first semiconductor substrate at a position adjacent to the first photodiode, and connected to a first upper interconnection layer of the first interconnection structure; and
a second floating diffusion node in the second region of the first semiconductor substrate at a position adjacent to the second photodiode, and connected to a second upper interconnection layer of the second interconnection structure,
wherein the second semiconductor structure comprises a first source follower transistor on the third surface of the second semiconductor substrate and overlapping the first region of the first semiconductor substrate, and a second source follower transistor overlapping the second region of the first semiconductor substrate,
wherein the first floating diffusion node is connected to the first source follower transistor through the first upper bonding structure and the first intermediate bonding structure, and
wherein the second floating diffusion node is connected to the second source follower transistor through the second upper bonding structure and the second intermediate bonding structure.

15. The image sensor of claim 13, wherein the first insulating liner and the second insulating liner comprise silicon nitride.

16. The image sensor of claim 13, wherein a height of each of the first and second upper bonding structures in a vertical direction is greater than a height of the first shielding structure in the vertical direction.

17. The image sensor of claim 13, further comprising a third semiconductor structure on a lower surface of the second semiconductor structure,
wherein the third semiconductor structure comprises:
a third semiconductor substrate;
a third interconnection structure disposed on the third semiconductor substrate; and
an upper bonding insulating film between the third interconnection structure and the second semiconductor structure.

18. The image sensor of claim 17, wherein a through-via hole extends through the second semiconductor substrate in a vertical direction,
wherein the second semiconductor structure further comprises:
a lower bonding insulating film extending to an inner wall of the through-via hole on the fourth surface of the second semiconductor substrate; and
an intermediate conductive pad in the through-via hole, penetrating the lower bonding insulating film and being connected to the second interconnection structure, and
wherein the third semiconductor structure further comprises a lower conductive pad connected to the intermediate conductive pad, electrically connected to the third interconnection structure, and surrounded on at least one side surface by the upper bonding insulating film.

19. The image sensor of claim 13, wherein the first shielding structure surrounds the extension portion and the pad portion of each of the first and second upper bonding structures.

20. A semiconductor device comprising:
a first semiconductor structure comprising a first semiconductor substrate, a first interconnection structure below the first semiconductor substrate, first bonding structures exposed from a lower surface of the first interconnection structure, and a first bonding insulating film surrounding lower regions of the first bonding structures;
a second semiconductor structure comprising a second semiconductor substrate, a second interconnection structure on the second semiconductor substrate, second bonding structures exposed from an upper surface of the second interconnection structure and bonded to each of the first bonding structures, a second bonding insulating film surrounding upper regions of the second bonding structures, a first backside insulating layer on a lower surface of the second semiconductor substrate, a third bonding insulating film on the first backside insulating layer, and a conductive through-via, wherein the conductive through-via overlaps the third bonding insulating film and the first backside insulating layer, and is electrically connected to the second interconnection structure; and
a third semiconductor structure comprising a third semiconductor substrate, a third interconnection structure on an upper surface of the third semiconductor substrate, a fourth bonding insulating film on the third interconnection structure and contacting the third bonding insulating film, and a bonding pad electrically connected to the third interconnection structure and bonded to the conductive through-via,
wherein each of the first bonding structures comprises a first plug portion contacting the first interconnection structure and having a first side surface, a first connection portion having a second side surface extending from the first side surface and having a width that increases with proximity to the second semiconductor structure, and a first pad portion extending from the second side surface and having a third side surface at least partially contacting the first bonding insulating film, and
wherein each of the second bonding structures comprises a second plug portion contacting the second interconnection structure and having a fourth side surface, a second connection portion having a fifth side surface extending from the fourth side surface and having a width that increases with proximity to the first semiconductor structure, and a second pad portion extending from the fifth side surface and having a sixth side surface at least partially contacting the second bonding insulating film.
